(19) United States
(12) Patent Application Publication
(10) Pub. No.: US 2026/0206387 A1
(43) Pub. Date: Jul. 16, 2026

(54) DISPLAY APPARATUS AND ELECTRONIC DEVICE INCLUDING THE SAME

(71) Applicant: Samsung Display Co., LTD., Yongin-si (KR)

(72) Inventor: Changil TAE, Yongin-si (KR)

(21) Appl. No.: 19/446,594

(22) Filed: Jan. 12, 2026

(30) Foreign Application Priority Data
Jan. 13, 2025 (KR) 10-2025-0004981

(51) Int. Cl. H10H 29/39; G09G 3/00; G09G 3/32

(52) U.S. Cl. CPC H10H 29/39; G09G 3/035; G09G 3/32; G09G 2300/0426; G09G 2300/0819; G09G 2300/0852; G09G 2300/0861; G09G 2320/0223; G09G 2320/0233; G09G 2320/0238

(57) ABSTRACT

A display apparatus includes: a substrate; a transistor disposed on the substrate; a first first electrode pad electrically connected to the transistor; a first first bump metal connected to the first first electrode pad; and a first light-emitting element electrically connected to the first first electrode pad through the first first bump metal, wherein, in a plan view, the first first bump metal includes a first depression portion concavely recessed inward from one edge thereof.

This application claims priority to Korean Patent Application No. 10-2025-0004981, filed on January 13, 2025, and all the benefits accruing therefrom under 35 U.S.C. §119, the content of which in its entirety is herein incorporated by reference.

### BACKGROUND

### 1 Field

### 2 Description of the Relate Art

Recently, electronic devices are widely used. Electronic devices are variously used as mobile electronic devices and fixed electronic devices. To support various functions, the electronic devices include a display apparatus which may provide visual information such as images to users.

With the development of display apparatuses that visually display various electrical signals, various display apparatuses having excellent characteristics such as being slim, being lightweight, having low power consumption, and the like have been introduced. As an example, flexible display apparatuses that are foldable or rollable in a roll shape have been introduced. Recently, research and development are actively carried out on display apparatuses of various structures, such as stretchable display apparatuses that may change into various shapes.

### SUMMARY

Embodiments of the invention may provide a display apparatus, for example, a flexible display apparatus, and an electronic device including the display apparatus.

An embodiment of the invention provides a display apparatus including: a substrate; a transistor disposed on the substrate; a first first electrode pad electrically connected to the transistor; a first first bump metal connected to the first first electrode pad; and a first light-emitting element electrically connected to the first first electrode pad through the first first bump metal, where, in a plan view, the first first bump metal includes a first depression portion concavely recessed inward from one edge thereof.

In an embodiment, the first light-emitting element may include a first electrode in contact with a portion of the first first bump metal, and in the plan view, the first depression portion may not to overlap the first electrode.

In an embodiment, the first first bump metal may be provided in a shape of a polygon in the plan view, and a first edge of the polygon may overlap the first electrode in the plan view, where the first depression portion may be provided in plurality, and a plurality of first depression portions may be respectively recessed from remaining edges other than the first edge.

In an embodiment, the first depression portion may have a shape recessed in a straight line shape from the one edge of the first first bump metal in the plan view.

In an embodiment, the first depression portion may have a shape recessed in an inverted 'T' shape from the one edge of the first first bump metal in the plan view.

In an embodiment, the first depression portion may be provided in plurality, and a plurality of first depression portions may be disposed apart from each other along one edge of the first first bump metal.

In an embodiment, in the plan view, the first first bump metal may have a smaller size than the first first electrode pad.

In an embodiment, the display apparatus may further include: a second first electrode pad apart in a first direction from the first first electrode pad; a second electrode pad apart from the first first electrode pad and the second first electrode pad in a second direction crossing the first direction; and a first second bump metal connected to the second electrode pad to electrically connect the second electrode pad and the first light-emitting element to each other, where, in a plan view, the first second bump metal may include a second depression portion concavely recessed inward from one edge thereof.

In an embodiment, the first depression portion may be recessed from a second edge of the first first bump metal opposite to a first edge of the first first bump metal, which is adjacent to the first second bump metal.

In an embodiment, the first light-emitting element may include a second electrode in contact with a portion of the first second bump metal, and in a plan view, the second depression portion may not to overlap the second electrode.

In an embodiment, the second depression portion may be recessed from a second edge of the first second bump metal opposite to a first edge of the first second bump metal, which is adjacent to the first first bump metal.

In an embodiment, the display apparatus may further include: a second second bump metal connected to the second electrode pad to electrically connect the second electrode pad and a second light-emitting element to each other; and a connection metal disposed on the second electrode pad to connect the first second bump metal and the second second bump metal to each other.

In an embodiment, in the plan view, a width of the connection metal may be less than widths of the first second bump metal and the second second bump metal.

In an embodiment, in the plan view, the first second bump metal may have a smaller size than the second electrode pad.

An embodiment of the invention provides a display apparatus including: a substrate; a transistor disposed on the substrate; a first first electrode pad electrically connected to the transistor; a first first bump metal connected to the first first electrode pad; and a first light-emitting element electrically connected to the first first electrode pad through the first first bump metal, where, in a plan view, the first first bump metal is provided with a first opening exposing the first first electrode pad.

In an embodiment, the first light-emitting element may include a first electrode in contact with a portion of the first first bump metal, and in the plan view, the first opening may be defined not to overlap the first electrode.

In an embodiment, the display apparatus may further include: a second first electrode pad apart in a first direction from the first first electrode pad; a second electrode pad apart from the first first electrode pad and the second first electrode pad in a second direction crossing the first direction; and a first second bump metal connected to the second electrode pad to electrically connect the second electrode pad and the first light-emitting element to each other, where, in the plan view, the first second bump metal may be provided with a second opening exposing the second electrode pad.

In an embodiment, the first light-emitting element may include a second electrode in contact with a portion of the first second bump metal, and in a plan view, the second opening may be defined not to overlap the second electrode.

In an embodiment, the display apparatus may further include: a second second bump metal connected to the second electrode pad to electrically connect the second electrode pad and a second light-emitting element to each other; and a connection metal disposed on the second electrode pad to connect the first second bump metal and the second second bump metal to each other.

An embodiment of the invention provides an electronic device including a display unit, where the electronic device includes: a display apparatus corresponding to the display unit; and a frame which accommodates the display apparatus, where the display apparatus includes: a substrate; a transistor disposed on the substrate; a first first electrode pad electrically connected to the transistor; a first first bump metal connected to the first first electrode pad; and a first light-emitting element electrically connected to the first first electrode pad through the first first bump metal, where, in a plan view, the first first bump metal includes a first depression portion concavely recessed inward from one edge thereof.

According to embodiments of the invention, a display apparatus capable of stably maintaining electrical connection of a light-emitting element, and an electronic device including the display apparatus may be provided.

Effects of embodiments of the invention are not limited to the above mentioned effects and other effects not mentioned may be clearly understood by those of ordinary skill in the art from the claims.

### BRIEF DESCRIPTION OF THE DRAWINGS

FIG. 1 is a schematic perspective view of a display apparatus according to an embodiment of the invention.

FIGS. 2A and 2B are perspective views of the display apparatus of FIG. 1 stretched in a first direction.

FIG. 2C is a perspective view of the display apparatus of FIG. 1 stretched in a second direction.

FIG. 2D is a perspective view of the display apparatus of FIG. 1 stretched in the first direction and the second direction.

FIG. 2E is a perspective view of the display apparatus of FIG. 1 stretched in a third direction.

FIG. 3 is a schematic plan view of a display apparatus according to an embodiment of the invention.

FIG. 4A is an enlarged plan view of a portion of a display apparatus, showing a portion IV of FIG. 3 according to an embodiment of the invention.

FIG. 4B is an enlarged plan view of a portion of a display apparatus, showing a portion IV of FIG. 3 according to an embodiment of the invention.

FIG. 4C is an enlarged plan view of a portion of a display apparatus, showing a portion IV of FIG. 3 according to an embodiment of the invention.

FIG. 5 is a schematic cross-sectional view of a first island portion and a first bridge portion disposed in a display area of a display apparatus according to an embodiment of the invention.

FIGS. 6A to 6C are equivalent circuit diagrams of a sub-pixel of a display apparatus according to an embodiment of the invention.

FIG. 7 is a schematic plan view of the display apparatus according to an embodiment of the invention.

FIGS. 8A to 8D are excerpted plan views of first and second electrode pads, a light-emitting diode, and a bump metal disposed in a first island portion of a display apparatus according to embodiments of the invention.

FIG. 9 is a cross-sectional view of a first island portion of a display apparatus according to an embodiment of the invention and corresponds to a cross-sectional view taken along line IX-IX' of FIG. 7.

FIG. 10 is an excerpted plan view of first and second electrode pads, a light-emitting diode, and a bump metal disposed in a first island portion of a display apparatus according to an embodiment of the invention.

FIG. 11 is an excerpted plan view of first and second electrode pads, a light-emitting diode, and a bump metal disposed in a first island portion of a display apparatus according to an embodiment of the invention.

FIGS. 12A to 12G are respectively schematic perspective views of an electronic device including a display apparatus according to an embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art .

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

not intended to be limiting. As used herein, "a", "an," "the," and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when an element is referred to as being “on” another element, it can be directly on the other element or intervening elements may be present therebetween. In contrast, when an element is referred to as being “directly on” another element, there are no intervening elements present.

It will be understood that when a layer, region, or element is referred to as being "connected" to another portion, it may be "directly connected" to the other portion or may be "indirectly connected" to the other portion with another layer, region, or element located therebetween. In addition, it will be understood that when a layer, region, or element is referred to as being "electrically connected" to another portion, it may be "directly electrically connected" to the other portion or may be "indirectly electrically connected" to the other portion with another layer, region, or element interposed therebetween.

Sizes of elements in the drawings may be exaggerated or reduced for convenience of explanation. As an example, the size and thickness of each element shown in the drawings are arbitrarily represented for convenience of description, and thus, the invention is not necessarily limited thereto.

In an embodiment below, when a wiring is referred to as "extending in a first direction or a second direction", it means that the wiring not only extends in a straight line shape but also extends in a zigzag or in a curve in the first direction or the second direction.

In an embodiment below, when referring to a "plan view", it means an object portion is viewed from above. In embodiments below, when referring to a "cross-sectional view", it means a cross-section of an object portion cut vertically is viewed from a side. In embodiments below, when it is referred that a first element "overlaps" a second element, the first element is arranged above or below the second element.

In an embodiment below, an x axis, a y axis, and a z axis are not limited to three axes of the rectangular coordinate system, and may be interpreted in a broader sense including the same. For example, the x axis, y axis, and z axis may be perpendicular to one another, or may represent different directions that are not perpendicular to one another.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

In the case where a certain embodiment may be implemented differently, a specific process order may be performed in the order different from the described order. As an example, two processes successively described may be simultaneously performed substantially and performed in the opposite order.

"About" or "approximately" as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, "about" can mean within one or more standard deviations, or within ± 30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described with reference to the accompanying drawings, where the same or like elements are given the same or like reference numerals in the drawings, and any repetitive detailed description thereof will be omitted or simplified.

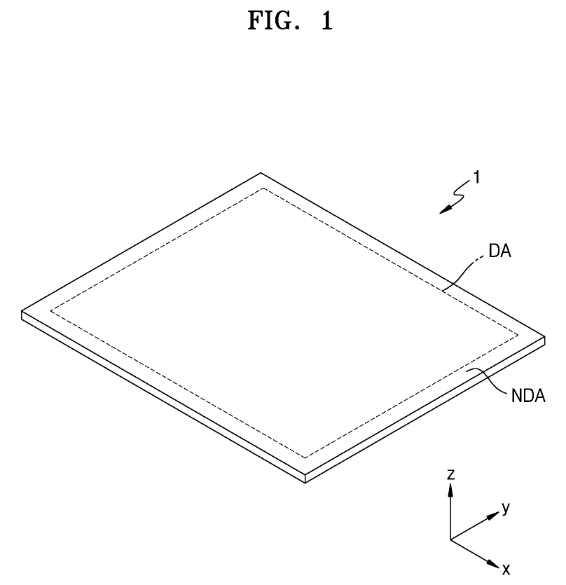

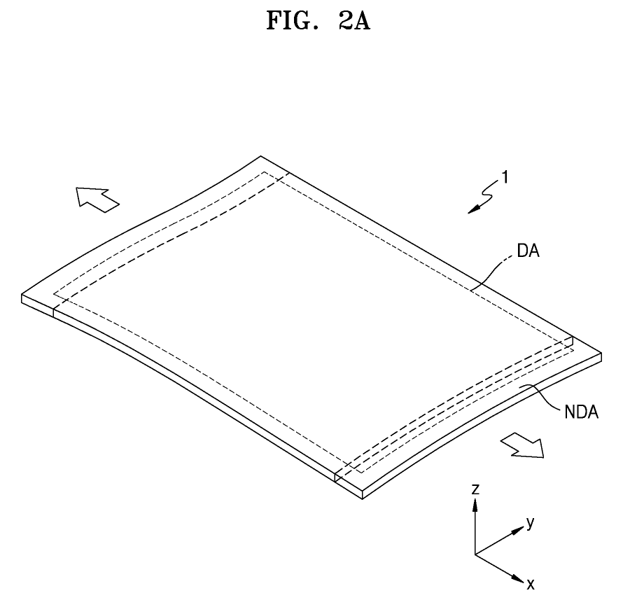

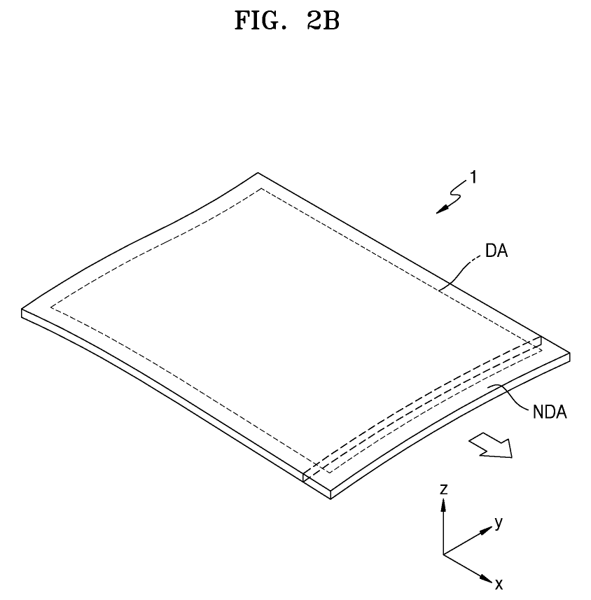

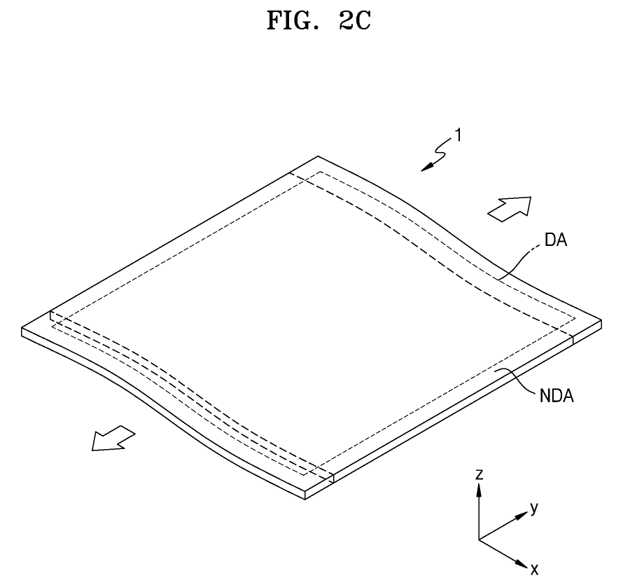

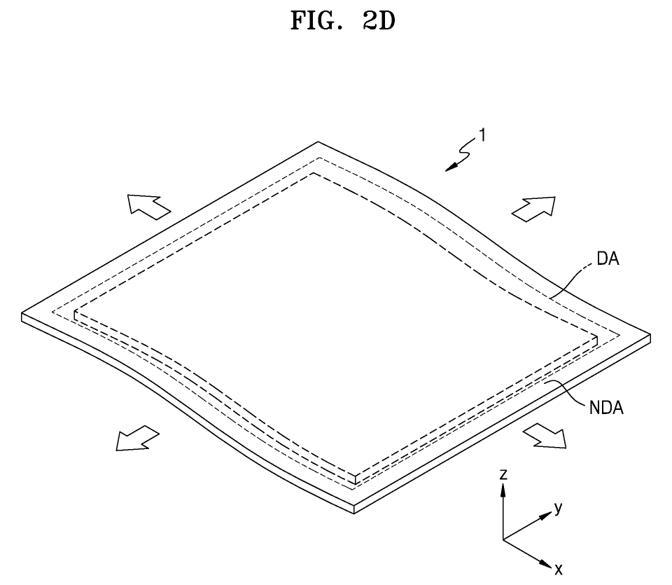

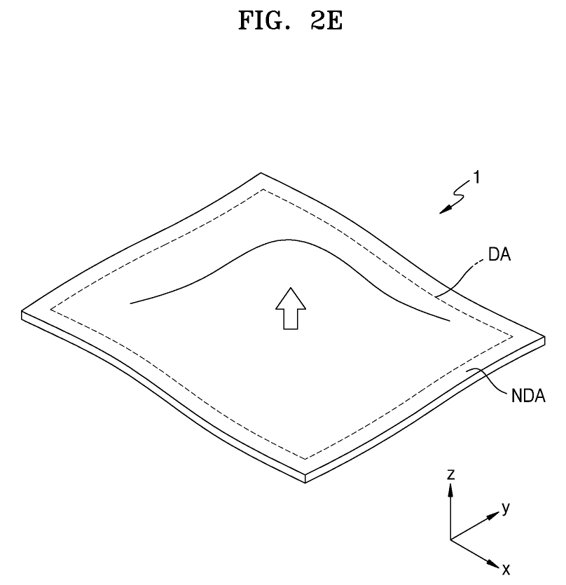

FIG. 1 is a schematic perspective view of a display apparatus 1 according to an embodiment of the invention. FIGS. 2A and 2B are perspective views of the display apparatus 1 of FIG. 1 stretched in a first direction. FIG. 2C is a perspective view of the display apparatus 1 of FIG. 1 stretched in a second direction. FIG. 2D is a perspective view of the display apparatus 1 of FIG. 1 stretched in the first direction and the second direction. FIG. 2E is a perspective view of the display apparatus 1 of FIG. 1 stretched in a third direction.

Referring to FIG. 1, an embodiment of the display apparatus 1 may include a display area DA and a non-display area NDA. The display area DA may include a plurality of pixels. The display apparatus 1 may be configured to display images by using light emitted from the plurality of pixels. The non-display area NDA may be disposed outside the display area DA. The non-display area NDA is a region in which the pixels are not disposed and may surround the display area DA entirely.

In an embodiment, the display apparatus 1 may be stretched or shrunk in various directions. The display apparatus 1 may be stretched in the first direction (e.g., an x direction and/or -x direction) by an external force exerted by an external object or a user. In an embodiment, as shown in FIGS. 2A and 2B, the display area DA and/or the non-display area NDA of the display apparatus 1 may be stretched in the first direction (e.g., the x direction and/or -x direction). In an embodiment, as shown in FIG. 2A, the display area DA and/or the non-display area NDA may be stretched in the x direction and -x direction, or as shown in FIG. 2B, be stretched in the x direction with one side of the display apparatus 1 fixed.

The display apparatus 1 may be stretched in the second direction (e.g., a y direction and/or -y direction) by an external force exerted by an external object or a user. In an embodiment, as shown in FIG. 2C, the display area DA and/or the non-display area NDA of the display apparatus 1 may be stretched in the y direction and -y direction. In another embodiment, the display apparatus 1 may be stretched in the y direction or -y direction with one side of the display apparatus 1 fixed.

The display apparatus 1 may be stretched in a plurality of directions, for example, the first direction (e.g., the x direction and/or -x direction) and the second direction (e.g., the y direction and/or -y direction) by an external force exerted by an external object or a portion of a person’s body. In an embodiment, as shown in FIG. 2D, the display area DA and/or the non-display area NDA of the display apparatus 1 may be stretched in the ±x directions and ±y directions.

The display apparatus 1 may be stretched in the third direction (e.g., a z direction and/or -z direction) by an external force exerted by an external object or a portion of a person's body. In an embodiment, FIG. 2E shows a portion of the display apparatus 1, for example, a partial region of the display area DA protrudes in the z direction. In another embodiment, a portion of the display apparatus 1, for example, a partial region of the display area DA may protrude in the -z direction (or be recessed in the z direction).

Although FIGS. 2A to 2E shows an embodiment where the display apparatus 1 is stretched in the first direction, the second direction, and/or the third direction, the invention is not limited thereto. In another embodiment, the display apparatus 1 may be variously transformed into an irregular shape, such as, by bending or twisting with two or more axes.

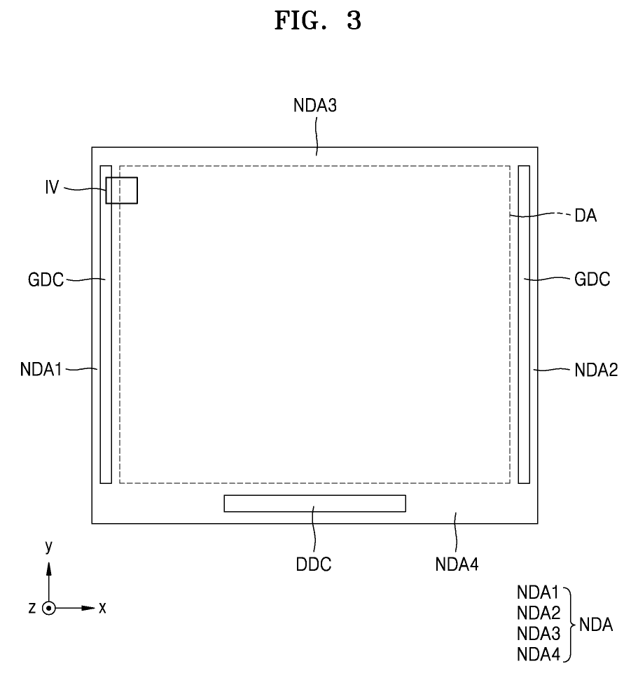

FIG. 3 is a schematic plan view of the display apparatus 1 according to an embodiment of the invention.

In an embodiment, the plurality of pixels may be arranged in the display area DA of the display apparatus 1. Each pixel may include sub-pixels emitting light of different colors from each other. A light-emitting element corresponding to each sub-pixel may be disposed in the display area DA. A circuit may be located in the non-display area NDA around the display area DA, and the circuit provides electrical signals to light-emitting elements disposed in the display area DA and transistors electrically connected to the light-emitting elements. A gate driving circuit GDC may be disposed in each of a first non-display area NDA1 and a second non-display area NDA2 disposed on two opposite sides with the display area DA therebetween. The gate driving circuit GDC may include drivers for providing electrical signals to a gate electrode of each of the transistors electrically connected to the light-emitting elements. Although FIG. 3 shows an embodiment where the gate driving circuit GDC is disposed in each of the first non-display area NDA1 and the second non-display area NDA2, the invention is not limited thereto. In another embodiment, the gate driving circuit GDC may be disposed in one of the first non-display area NDA1 and the second non-display area NDA2.

A data driving circuit DDC may be disposed in a third non-display area NDA3 and/or a fourth non-display area NDA4 connecting the first non-display area NDA1 and the second non-display area NDA2 to each other. In an embodiment, as shown in FIG. 3, the data driving circuit DDC may be disposed in the fourth non-display area NDA4. In another embodiment, the data driving circuit DDC may be disposed in each of the third non-display area NDA3 and the fourth non-display area NDA4.

Although FIG. 3 shows an embodiment where the data driving circuit DDC is disposed in the fourth non-display area NDA4 of the display apparatus 1, the invention is not limited thereto. In another embodiment, the display apparatus 1 may further include a flexible circuit board (not shown) electrically connected through a terminal section (not shown) disposed in the fourth non-display area NDA4, and the data driving circuit DDC may be disposed on the flexible circuit board.

In another embodiment, an elongation of the non-display area NDA may be equal to or less than an elongation of the display area DA. In an embodiment, an elongation of the non-display area NDA may be different for each region. In an embodiment, for example, the first non-display area NDA1, the second non-display area NDA2, and the third non-display area NDA3 may have substantially a same elongation, but an elongation of the fourth non-display area NDA4 may be less than an elongation of each of the first non-display area NDA1, the second non-display area NDA2, and the third non-display area NDA3. In the disclosure, an elongation is a numerical value representing a change (ΔL/L) in length by which the display apparatus 1 may be stretched without physical damage to the display apparatus 1 when an external force is applied to the display apparatus 1. Here, ΔL denotes the amount of change in length of the display apparatus 1, and L denotes an initial length of the display apparatus 1.

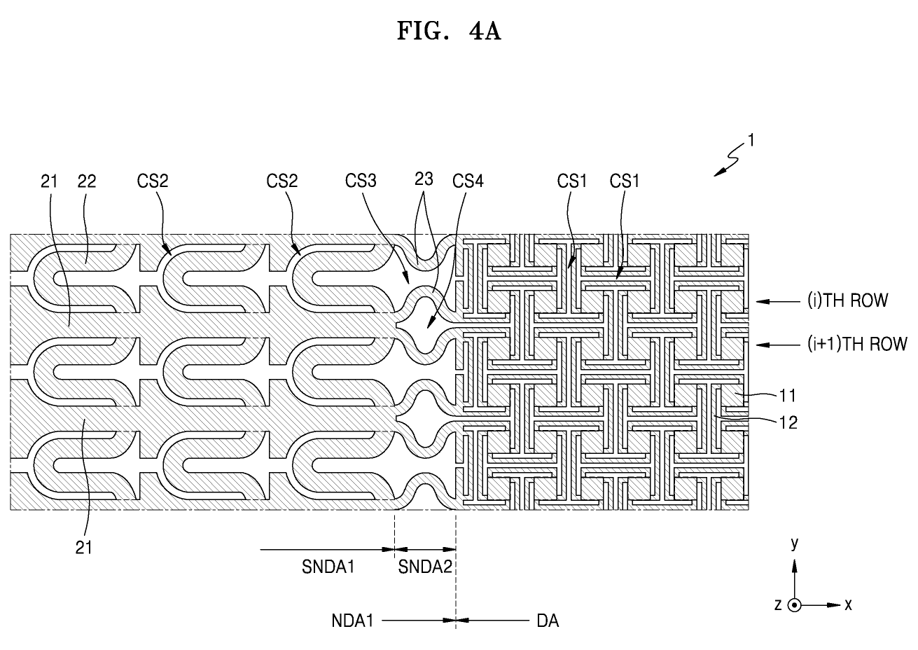

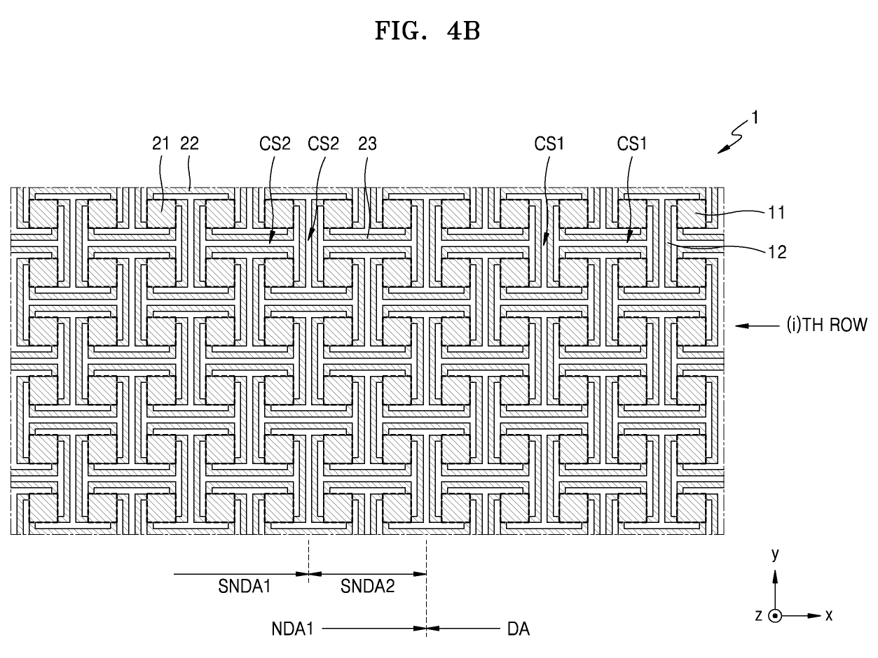

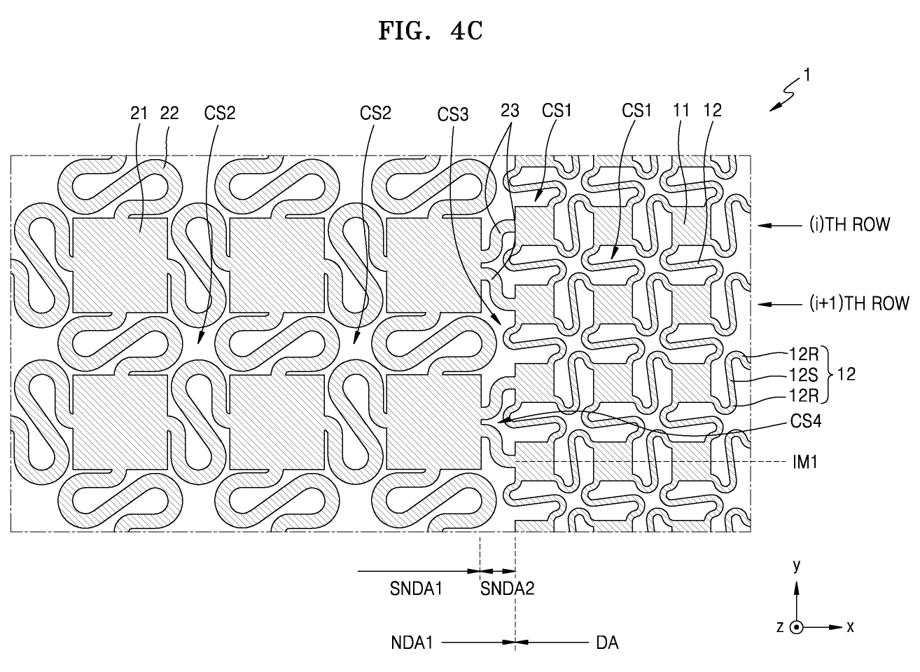

FIG. 4A is an enlarged plan view of a portion of the display apparatus 1, showing a portion IV of FIG. 3 according to an embodiment of the invention.

Referring to FIG. 4A, an embodiment of the display apparatus 1 may include first island portions 11 and first bridge portions 12 connecting (or connected between) adjacent first island portions 11, where the first island portions 11 are apart from each other in the first direction (e.g., the x direction or -x direction) and the second direction (e.g., the y direction or -y direction) in the display area DA.

Each first island portion 11 may be connected to a plurality of first bridge portions 12. In an embodiment, for example, each first island portion 11 may be connected to four first bridge portions 12. Two first bridge portions 12 may be disposed on two opposite sides of the first island portion 11 in the first direction (e.g., the x direction or -x direction), and the remaining two first bridge portions 12 may be disposed on two opposite sides of the first island portion 11 in the second direction (e.g., the y direction or -y direction). In an embodiment, four first bridge portions 12 may be respectively connected to four sides of the first island portion 11. Four first bridge portions 12 may be respectively adjacent to the corners of the first island portion 11.

The first bridge portions 12 may be apart from each other by a first opening CS1 defined between the first bridge portions 12. In an embodiment, the first opening CS1 having an approximate ‘H’ shape and a first opening CS1 having an approximate ‘I’ shape that is obtained by rotating the H shape by about 90° may be alternately and repeatedly arranged in the first direction (e.g., the x direction or -x direction) and the second direction (e.g., the y direction or -y direction). Two opposite ends of each first bridge portion 12 are respectively connected to adjacent first island portions 11, and one side of each first bridge portion 12 may be apart from one side of an adjacent first island portion 11 and/or one side of another first bridge portion 12 by the first opening CS1.

The display apparatus 1 may include second island portions 21 apart from each other, and second bridge portions 22 connecting (or connected between) adjacent second island portions 21 in the non-display area, for example, the first non-display area NDA1 shown in FIG. 4A.

Each second island portion 21 may extend in the first direction (e.g., the x direction or -x direction). The second island portions 21 may be apart from each other in the second direction (e.g., the y direction or -y direction) crossing the first direction (e.g., the x direction or -x direction). Each second island portion 21 may include drivers of the gate driving circuit GDC (FIG. 2) described with reference to FIG. 3.

The second bridge portion 22 may have a serpentine shape. The length of the second bridge portion 22 may be greater than the shortest distance between adjacent second island portions 21 in the second directions (e.g., the y direction or -y direction). In an embodiment, the second bridge portion 22 may approximately have an approximate omega (Ω) shape that is convex toward the first direction (e.g., the x direction or -x direction). The second bridge portions 22 may be disposed between adjacent second island portions 21 and be apart from each other.

The second bridge portions 22 between adjacent second island portions 21 may be apart from each other by a second opening CS2. Between adjacent second island portions 21, the second openings CS2 and the second bridge portions 22 may be alternately arranged in the first direction (e.g., the x direction or -x direction). The second openings CS2 may have a same shape as each other. Two opposite ends of each second bridge portion 22 are respectively connected to adjacent second island portions 21, and one side of each second bridge portion 22 may be apart from one side of an adjacent second island portion 21 and/or one side of another second bridge portion 22 by the second opening CS2.

One of the second island portions 21 disposed in the first non-display area NDA1 may correspond to first island portions 11 in a plurality of rows arranged in the display area DA. In an embodiment, for example, one of the second island portions 21 disposed in the first non-display area NDA1 may correspond to first island portions 11 arranged in an i-th row in the display area DA, and first island portions 11 arranged in an (i+1)-th row in the display area DA (here, i is a positive integer greater than 0). Although FIG. 4A shows an embodiment where the second island portion 21 corresponds to two rows of the first island portions 11, the invention is not limited thereto. In another embodiment, one of second island portions 21 disposed in the first non-display area NDA1 may correspond to n rows of the first island portions 11 disposed in the display area DA (here, i is a positive integer equal to or greater than 3).

The non-display area, for example, the first non-display area NDA1, may include a first sub-non-display area SNDA1 in which the second island portions 21 and the second bridge portions 22 are disposed, and a second sub-non-display area SNDA2 between the first sub-non-display area SNDA1 and the display area DA. Third bridge portions 23 may be disposed in the second sub-non-display area SNDA2, where the third bridge portions 23 connect the display area DA to the first sub-non-display area SNDA1. One end of the third bridge portion 23 may be connected to the second island portion 21 and/or the second bridge portion 22, and another end of the third bridge portion 23 may be connected to the first island portion 11 and/or the first bridge portion 12.

The third bridge portion 23 may have a serpentine shape. In an embodiment, the shape of the third bridge portion 23 may be different from the shape of each of the first bridge portion 12 and the second bridge portion 22. In an embodiment, as shown in FIG. 4A, the third bridge portion 23 may approximately have an approximate omega (Ω) shape that is convex toward the second direction (e.g., the y direction or -y direction). The third bridge portions 23 may have a symmetrical structure in which one of adjacent third bridge portions 23 arranged in the second direction (e.g., the y direction or -y direction) may be convex in the y direction and the other may be convex in the -y direction. Between the third bridge portions 23, a structure in which a third opening CS3 and a fourth opening CS4 having different shapes are repeated may be provided. The width of the third bridge portion 23 may be different from the width of the first bridge portion 12 and the width of the second bridge portion 22. In an embodiment, the width of the third bridge portion 23 may be greater than the width of the first bridge portion 12 and less than the width of the second bridge portion 22.

In an embodiment, as shown in FIG. 4A, the second island portion 21 and the second bridge portion 22 in the non-display area, for example, the first non-display area NDA1, may respectively have shapes different from the shapes of the first island portion 11 and the first bridge portion 12 in the display area DA. In another embodiment of the invention, the second island portion 21 and the second bridge portion 22 in the non-display area may respectively have a same shape as the shape of the first island portion 11 and the first bridge portion 12 in the display area DA.

FIG. 4B is an enlarged plan view of a portion of the display apparatus 1, showing a portion IV of FIG. 3 according to an embodiment of the invention.

Referring to FIG. 4B, an embodiment of the display apparatus 1 includes the first island portions 11 apart from each other in the display area DA, and the first bridge portions 12 apart from each other by the first opening CS1 and connecting adjacent first island portions 11 to each other. The structure of the display area DA in FIG. 4B may be the same as the structure of the display area DA described above with reference to FIG. 4A.

The display apparatus 1 may include the second island portions 21 and the second bridge portions 22 disposed in the non-display area, for example, the first non-display area NDA1. In an embodiment, the second island portions 21 and the second bridge portions 22 may respectively have the same shapes as the shapes of the first island portions 11 and the first bridge portions 12.

The second island portions 21 may be apart from each other in the first direction (e.g., the x direction or -x direction) and the second direction (e.g., the y direction or -y direction) in the non-display area, for example, the first non-display area NDA1. Each of the second bridge portions 22 may connect adjacent second island portions 21 to each other. The second bridge portions 22 may be apart from each other by a second opening CS2 defined between the second bridge portions 22.

The second opening CS2 may have substantially the same shape as the shape of the first opening CS1. In an embodiment, for example, the second opening CS2 having an approximate ‘H’ shape and the second opening CS2 having an approximate ‘I’ shape may be alternately and repeatedly arranged in the non-display area, for example, the first non-display area NDA1. Two opposite ends of each second bridge portion 22 are respectively connected to adjacent second island portions 21, and one side of each second bridge portion 22 may be apart from one side of an adjacent second island portion 21 and/or one side of another second bridge portion 22 by the second opening CS2.

Each second island portion 21 may be connected to four second bridge portions 22. Each second island portion 21 may include drivers of the gate driving circuit GDC (FIG. 2) described with reference to FIG. 3.

The second island portions 21 in one of rows disposed in the first non-display area NDA1 may correspond to first island portions 11 in one of rows arranged in the display area DA. In an embodiment, for example, the second island portions 21 arranged in an i-th row in the first direction (e.g., the x direction or -x direction) in the first non-display area NDA1 may correspond to the first island portions 11 arranged in the same row, for example, the i-th row in the display area DA (here, i is a positive number greater than 0).

The display apparatus 1 may include the third bridge portions 23 disposed in the second sub-non-display area SNDA2 connecting the display area DA to the first sub-non-display area SNDA1. The non-display area, for example, the first non-display area NDA1, may include the first sub-non-display area SNDA1 in which the second island portions 21 and the second bridge portions 22 are disposed, and the second sub-non-display area SNDA2 including the third bridge portions 23 and located between the first sub-non-display area SNDA1 and the display area DA. The third bridge portion 23 may be substantially the same as the first bridge portion 12 and the second bridge portion 22. In an embodiment, for example, the width of the third bridge portion 23 may be the same as the width of the first bridge portion 12 and the width of the second bridge portion 22.

FIG. 4C is an enlarged plan view of a portion of a display apparatus, showing a portion IV of FIG. 3 according to an embodiment of the invention.

Referring to FIG. 4C, an embodiment of the display apparatus 1 may include first island portions 11 and first bridge portions 12 connecting adjacent first island portions 11 to each other, where the first island portions 11 are apart from each other in the first direction (e.g., the x direction or -x direction) and the second direction (e.g., the y direction or -y direction) in the display area DA.

The first bridge portions 12 may be apart from each other by a first opening CS1 located between the first bridge portions 12. The first bridge portion 12 may have a serpentine shape. In an embodiment, for example, as shown in FIG. 4C, the first bridge portion 12 may have a shape of an approximate 'S' such as including two round portions 12R and a straight portion 12S between the two round portions 12R.

Each first island portion 11 may be connected to a plurality of first bridge portions 12. In an embodiment, for example, each first island portion 11 may be connected to four first bridge portions 12. Two first bridge portions 12 may be disposed on two opposite sides of the first island portion 11 in the first direction (e.g., the x direction or -x direction), and the remaining two first bridge portions 12 may be disposed on two opposite sides of the first island portion 11 in the second direction (e.g., the y direction or -y direction). Four first bridge portions 12 may be respectively connected to four sides of the first island portion 11. Four first bridge portions 12 may be respectively adjacent to the corners of the first island portion 11.

In the non-display area, for example, the first non-display area NDA1 shown in FIG. 4C, the display apparatus 1 may include the second island portions 21 apart from each other in the first direction (e.g., the x direction or -x direction) and the second direction (e.g., the y direction or -y direction), and the second bridge portions 22 connecting adjacent second island portions 21 to each other.

The second bridge portions 22 may be apart from each other by a second opening CS2 located between the second bridge portions 22. The second bridge portion 22 may have a serpentine shape. In an embodiment, for example, as shown in FIG. 4C, the second bridge portion 22 may approximately have a 'S' shape. The size and/or width of the second bridge portion 22 may be different from the size and/or width of the first bridge portion 12. In an embodiment, for example, the size and/or width of the second bridge portion 22 may be greater than the size and/or width of the first bridge portion 12. The curvature radius of a round portion of the second bridge portion 22 may be different from the curvature radius of a round portion of the first bridge portion 12. In an embodiment, for example, the curvature radius of a round portion of the second bridge portion 22 may be greater than the curvature radius of a round portion of the first bridge portion 12.

Each second island portion 21 may be connected to a plurality of second bridge portions 22. Each second island portion 21 may be connected to four second bridge portions 22. Two second bridge portions 12 may be disposed on two opposite sides of the second island portion 21 in the first direction (e.g., the x direction or -x direction), and the remaining two second bridge portions 22 may be disposed on two opposite sides of the second island portion 21 in the second direction (e.g., the y direction or -y direction). In an embodiment, four second bridge portions 22 may be respectively connected to four sides of the second island portion 21. Each second bridge portion 22 may be connected to the central portion of each side of the second island portion 21.

The second island portions 21 in one of rows disposed in the first non-display area NDA1 may correspond to the first island portions 11 in a plurality of rows arranged in the display area DA. In an embodiment, for example, the second island portions 21 in one of rows disposed in the first non-display area NDA1 may correspond to first island portions 11 arranged in an i-th row in the display area DA, and first island portions 11 arranged in an (i+1)-th row in the display area DA (here, i is a positive integer greater than 0). In another embodiment, the second island portions 21 in one of rows may correspond to n rows of first island portions 11 (here, n is a positive number equal to or greater than 3).

The non-display area, for example, the first non-display area NDA1, may include a first sub-non-display area SNDA1 in which the second island portions 21 and the second bridge portions 22 are disposed, and a second sub-non-display area SNDA2 between the first sub-non-display area SNDA1 and the display area DA. Third bridge portions 23 may be disposed in the second sub-non-display area SNDA2, where the third bridge portions 23 connect the display area DA to the first sub-non-display area SNDA1. One end of the third bridge portion 23 may be connected to the second island portion 21, and the other end of the third bridge portion 23 may be connected to the first island portion 11. In an embodiment, for example, one end of the third bridge portion 23 may be connected to the central portion of one side of the second island portion 21, and the other end of the third bridge portion 23 may be connected to the central portion of one side of the first island portion 11.

The third bridge portion 23 may have a serpentine shape. In an embodiment, the shape of the third bridge portion 23 may be different from the shape of each of the first bridge portion 12 and the second bridge portion 22. The width of the third bridge portion 23 may be different from the width of the first bridge portion 12 and the width of the second bridge portion 22. The width of the third bridge portion 23 may be greater than the width of the first bridge portion 12 and less than the width of the second bridge portion 22. Between the third bridge portions 23 in the second direction (e.g., the y direction or -y direction), the third opening CS3 and the fourth opening CS4 having different shapes may be alternately disposed.

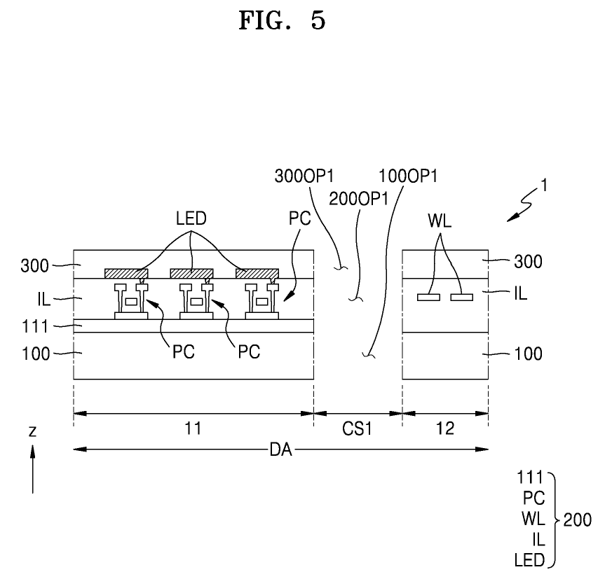

FIG. 5 is a schematic cross-sectional view of the first island portion 11 and the first bridge portion 12 disposed in the display area DA of the display apparatus 1 according to an embodiment.

Referring to FIG. 5, in an embodiment, the first island portion 11 and the first bridge portion 12 disposed in the display area DA may be apart from each other with the first opening CS1 therebetween. The first island portion 11 may include light-emitting elements LED and a circuit electrically connected thereto and driving the light-emitting element LED, for example, a pixel driving circuit PC, and the first bridge portions 11 may include a wiring WL electrically connected to the pixel driving circuits PC disposed in each of adjacent first island portions 11.

In the first island portion 11, a buffer layer 111 including an inorganic insulating material may be disposed on the substrate 100, and the pixel driving circuit PC may be disposed on the buffer layer 111. An insulating layer IL including an inorganic insulating material and/or an organic insulating material may be disposed between the pixel driving circuit portion PC and the light-emitting element LED. The light-emitting element LED may be disposed on the insulating layer IL and electrically connected to the pixel driving circuit portion PC corresponding thereto. The light-emitting elements LED may emit light of different colors or light of a same color. In an embodiment, the light-emitting elements LED may be configured to emit red, green, or blue light. In an embodiment, the light-emitting elements LED may be configured to emit white light. In another embodiment, the light-emitting elements LED may emit red, green, blue, and white light.

The substrate 100 may include polymer resin such as polyethersulfone, polyarylate, polyetherimide, polyethylene naphthalate, polyethylene terephthalate, polyphenylene sulfide, polyimide, polycarbonate, cellulose tri acetate, cellulose acetate propionate, and the like. In an embodiment, the substrate 100 may be a single layer including the polymer resin. In another embodiment, the substrate 100 may have a multi-layered structure including a base layer and a barrier layer, where the base layer includes the above polymer resin and the barrier layer includes an inorganic insulating material. The substrate 100 including the polymer resin may be flexible, rollable, or bendable.

In an embodiment, as shown in FIG. 5, three pixel driving circuits PC may be disposed in each first island portion 11, and three light-emitting elements LED may be respectively connected to the pixel driving circuits PC, but the disclosure is not limited thereto. In another embodiment, the number of pixel driving circuits PC and the number of light-emitting elements LED disposed in the first island portion 11 may be one, two, or four or more.

An encapsulation layer 300 may be disposed on the light-emitting element LED and may protect the light-emitting element LED from an external force and/or moisture transmission. The encapsulation layer 300 may include an inorganic encapsulation layer and/or an organic encapsulation layer. In an embodiment, the encapsulation layer 300 may include a structure in which an inorganic encapsulation layer including an inorganic insulating material, an organic encapsulation layer including an organic insulating material, and an inorganic encapsulation layer including an inorganic insulating material are stacked. In another embodiment, the encapsulation layer 300 may include an organic material such as resin. In an embodiment, the encapsulation layer 300 may include urethane epoxy acrylate. The encapsulation layer 300 may include a photosensitive material, for example, a material such as photoresist.

In the first bridge portion 12, the insulating layer IL including an organic insulating material may be disposed on the substrate 100. When the display apparatus 1 stretches, the first bridge portion 12, which is relatively subject to a large amount of transformation, may not have a layer including an inorganic insulating material that is prone to cracking, unlike the first island portion 11.

In an embodiment, the substrate 100 corresponding to the first bridge portion 12 may have a same stack structure as a stack structure of the substrate 100 corresponding to the first island portion 11. In an embodiment, the substrate 100 corresponding to the first bridge portion 12 and the substrate 100 corresponding to the first island portion 11 may be polymer resin layers simultaneously formed during the same process. In another embodiment, the substrate 100 corresponding to the first bridge portion 12 may have a different stack structure from a stack structure of the substrate 100 corresponding to the first island portion 11. In an embodiment, the substrate 100 corresponding to the first island portion 11 may have a multi-layered structure including a base layer that includes a polymer resin and a barrier layer that includes an inorganic insulating material, and the substrate 100 corresponding to the first bridge portion 12 may have a structure of a polymer resin layer in which a layer including an inorganic insulating material is absent.

In an embodiment, as described above, the wirings WL of the first bridge portion 12 may be signal lines (e.g., a gate line, a data line, and the like) for providing electrical signals, or voltage lines (e.g., a driving voltage line, an initialization voltage line, and the like) for providing voltages to transistors included in the pixel driving circuit PC of the first island portion 11. The encapsulation layer 300 may be disposed on also the first bridge portion 12. In another embodiment, the encapsulation layer 300 may not be present on the first bridge portion 12.

Referring to FIGS. 4A to 4C, and 5, the substrate 100 corresponding to the first island portion 11 may be connected to the substrate 100 corresponding to the first bridge portion 12. In other words, the plan views shown in FIGS. 4A to 4C may be substantially same as the plan view of the substrate 100 in FIG. 5. In other words, the substrate 100 may include a region corresponding to the first island portion 11, a region corresponding to the first bridge portion 12, and an opening 100OP1 having a same shape as a shape of the first opening CS1.

Similarly, the encapsulation layer 300 corresponding to the first island portion 11 and the encapsulation layer 300 corresponding to the first bridge portion 12 may be connected to each other. In an embodiment, for example, the plan views shown in FIGS. 4A to 4C may be substantially the same as the plan view of the encapsulation layer 300. In other words, the encapsulation layer 300 may include a region corresponding to the first island portion 11, a region corresponding to the first bridge portion 12, and an opening 300OP1 having the same shape as a shape of the first opening CS1.

A circuit-light-emitting element layer 200 between the substrate 100 and the encapsulation layer 300 may include the buffer layer 111, the pixel driving circuit portion PC, the wiring WL, the insulating layer IL, and the light-emitting element LED. Similar to the substrate 100, the plan views shown in FIGS. 4A to 4C may be substantially the same as the plan view of the circuit-light-emitting element layer 200. In other words, the circuit-light-emitting element layer 200 may be provided with an opening 200OP1 having a same shape as a shape of the first opening CS1.

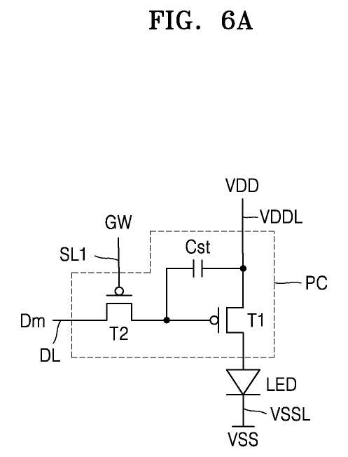

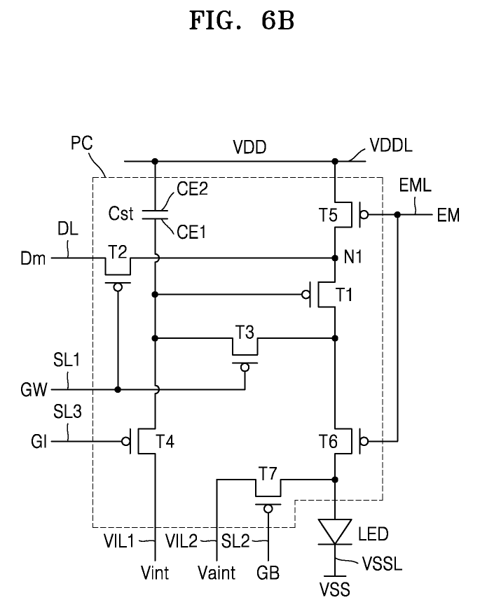

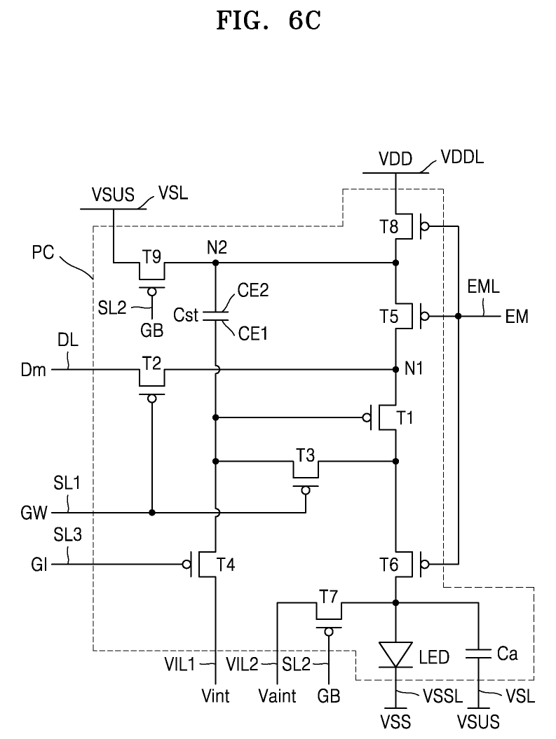

FIGS. 6A to 6C are equivalent circuit diagrams of a sub-pixel of the display apparatus 1 according to an embodiment.

Referring to FIG. 6A, in an embodiment, the light-emitting element LED corresponding to a sub-pixel may be electrically connected to the pixel driving circuit portion PC, and the pixel driving circuit portion PC may include a first transistor T1, a second transistor T2, and a storage capacitor Cst. The pixel driving circuit portion PC may be electrically connected to a signal line and a voltage line. The signal line may include a gate line such as a first scan line SL1, and a data line DL, and the voltage line may include a first voltage line VDDL.

The second transistor T2 may be electrically connected to the first scan line SL1 and the data line DL. The first scan line SL1 may provide a first scan signal GW1 to a gate electrode of the second transistor T2. The second transistor T2 is configured to transfer a data signal Dm to the first transistor T1 in response to a first scan signal GW1 input from the first scan line SL1, where the data signal Dm is input from the data line DL.

The storage capacitor Cst may be electrically connected to the second transistor T2 and the first voltage line VDDL and may store a voltage corresponding to a difference between a voltage transferred from the second transistor T2 and a first power voltage VDD supplied by the first voltage line VDDL.

The first transistor T1 is a driving transistor and may control a driving current flowing through the light-emitting element LED. The first transistor T1 may be connected to the first voltage line VDDL and the storage capacitor Cst. The first transistor T1 may control the driving current flowing from the first voltage line VDDL to the light-emitting element LED in response to a voltage value stored in the storage capacitor Cst. The light-emitting element LED may emit light having a preset brightness based on the driving current. A first electrode of the light-emitting element LED may be electrically connected to the first transistor T1, and a second electrode may be electrically connected to a second voltage line VSSL supplying a second power voltage VSS.

Although FIG. 6A shows an embodiment where the pixel driving circuit portion PC includes two transistors and one storage capacitor, the pixel driving circuit portion PC may include three or more transistors in another embodiment.

Referring to FIG. 6B, in another embodiment, the pixel driving circuit portion PC may include the first transistor T1, the second transistor T2, a third transistor T3, a fourth transistor T4, a fifth transistor T5, a sixth transistor T6, a seventh transistor T7, and the storage capacitor Cst.

The pixel driving circuit portion PC is electrically connected to signal lines and voltage lines. The signal lines may include a gate line such as the first scan line SL1, a second scan line SL2, a third scan line SL3, and an emission control line EML, and the data line DL. The voltage lines may include first and second initialization voltage lines VIL1 and VIL2 and the first voltage line VDDL.

The first voltage line VDDL may transfer the first power voltage VDD to the first transistor T1. The first initialization voltage line VIL1 may transfer a first initialization voltage Vint to the pixel driving circuit portion PC, where the first initialization voltage Vint initializes the first transistor T1. The second initialization voltage line VIL2 may transfer a second initialization voltage Vaint to the pixel driving circuit portion PC, where the second initialization voltage Vaint initializes the first electrode of the light-emitting element LED.

The first transistor T1 may be connected to the first voltage line VDDL through the fifth transistor T5 and electrically connected to the light-emitting element LED through the sixth transistor T6. The first transistor T1 serves as a driving transistor, and receives a data signal Dm and supplies the driving current to the light-emitting element LED based on a switching operation of the second transistor T2.

The second transistor T2 is a data-write transistor and is electrically connected to the first scan line SL1 and the data line DL. The second transistor T2 is electrically connected to the first voltage line VDDL through the fifth transistor T5. The second transistor T2 is turned on in response to a first scan signal GW transferred through the first scan line SL1, and performs a switching operation of transferring a data signal Dm to a first node N1, where the data signal Dm is transferred through the data line DL.

The third transistor T3 is electrically connected to the first scan line SL1 and electrically connected to the light-emitting element LED through the sixth transistor T6. The third transistor T3 may be turned on according to a first scan signal GW to diode-connect the first transistor T1, where the first scan signal GW is transferred through the first scan line SL1.

The fourth transistor T4 serves as a first initialization transistor and is electrically connected to the third scan line SL3 and the first initialization voltage line VIL1. The fourth transistor T4 may be turned on in response to a third scan signal GI to initialize a voltage of the gate electrode of the first transistor T1 by transferring the first initialization voltage Vint to the gate electrode of the first transistor T1, where the first initialization voltage Vint is from the first initialization voltage line VIL1, and the third scan signal GI is transferred through the third scan line SL3. The third scan signal GI may correspond to a first scan signal of another pixel driving circuit portion disposed in a previous row of the relevant pixel driving circuit portion PC.

The fifth transistor T5 may be an operation control transistor, and the sixth transistor T6 may be an emission control transistor. The fifth transistor T5 and the sixth transistor T6 may be electrically connected to the emission control line EML, simultaneously turned on according to an emission control signal EM transferred through the emission control line EML, and may form a current path such that the driving current flows in a direction from the first voltage line VDDL to the light-emitting element LED.

The seventh transistor T7 serves as a second initialization transistor and may be electrically connected to the second scan line SL2, the second initialization voltage line VIL2, and the sixth transistor T6. The seventh transistor T7 is turned on in response to a second scan signal GB transferred through the second scan line SL2, and is connected to transfer the second initialization voltage Vaint from the second initialization voltage line VIL2 to the first electrode of the light-emitting element LED, thereby initializing the first electrode of the light-emitting element LED.

The storage capacitor Cst includes a first electrode CE1 and a second electrode CE2. The first electrode CE1 is electrically connected to the gate electrode of the first transistor T1, and the second electrode CE2 is electrically connected to the first voltage line VDDL. The storage capacitor Cst may maintain a voltage applied to the gate electrode of the first transistor T1 by storing and maintaining a voltage corresponding to a difference between voltages of two opposite ends of the gate electrode of the first transistor T1 and the first voltage line VDDL.

Referring to FIG. 6C, in another embodiment, the pixel driving circuit portion PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst, and an auxiliary capacitor Ca.

The pixel driving circuit portion PC is electrically connected to signal lines and voltage lines. The signal lines may include a gate line such as the first scan line SL1, the second scan line SL2, the third scan line SL3, and the emission control line EML, and the data line DL. The voltage lines may include the first and second initialization voltage lines VIL1 and VIL2, a sustain voltage line VSL, and the first voltage line VDDL.

The first voltage line VDDL may transfer the first power voltage VDD to the first transistor T1. The first initialization voltage line VIL1 may transfer the first initialization voltage Vint to the pixel driving circuit portion PC, where the first initialization voltage Vint initializes the first transistor T1. The second initialization voltage line VIL2 may transfer the second initialization voltage Vaint to the pixel driving circuit portion PC, where the second initialization voltage Vaint initializes the first electrode of the light-emitting element LED. The sustain voltage line VSL may provide a sustain voltage VSUS to a second node N2, for example, the second electrode CE2 of the storage capacitor Cst during an initialization section and a data-write section.

The first transistor T1 may be electrically connected to the first voltage line VDDL through the fifth transistor T5 and the eighth transistor T8 and electrically connected to the light-emitting element LED through the sixth transistor T6. The first transistor T1 serves as a driving transistor, and may receive a data signal Dm and supply the driving current to the light-emitting element LED based on a switching operation of the second transistor T2.

The second transistor T2 is electrically connected to the first scan line SL1 and the data line DL and electrically connected to the first voltage line VDDL through the fifth transistor T5 and the eighth transistor T8. The second transistor T2 may be turned on in response to a first scan signal GW transferred through the first scan line SL1 and may perform a switching operation of transferring a data signal Dm to the first node N1, where the data signal Dm is transferred through the data line DL.

The third transistor T3 is electrically connected to the first scan line SL1 and electrically connected to the light-emitting element LED through the sixth transistor T6. The third transistor T3 may be turned on according to a first scan signal GW to compensate for a threshold voltage of the first transistor T1 by diode-connecting the first transistor T1, where the first scan signal GW is transferred through the first scan line SL1.

The fourth transistor T4 is electrically connected to the third scan line SL3 and the first initialization voltage line VIL1, turned on in response to a third scan signal GI transferred through the third scan line SL3, and initializes a voltage of the gate electrode of the first transistor T1 by transferring the first initialization voltage Vint from the first initialization voltage line VIL1 to the gate electrode of the first transistor T1. The third scan signal GI may correspond to a first scan signal of another pixel driving circuit portion disposed in a previous row of the relevant pixel driving circuit portion PC.

The fifth transistor T5, the sixth transistor T6, and the eighth transistor T8 may be electrically connected to the emission control line EML, simultaneously turned on in response to an emission control signal EM transferred through the emission control line EML, and may form a current path such that the driving current flows in a direction from the first voltage line VDDL to the light-emitting element LED.

The seventh transistor T7 serves as a second initialization transistor and may be electrically connected to the second scan line SL2, the second initialization voltage line VIL2, and the sixth transistor T6. The seventh transistor T7 is turned on in response to a second scan signal GB transferred through the second scan line SL2, and is connected to transfer the second initialization voltage Vaint from the second initialization voltage line VIL2 to the first electrode of the light-emitting element LED, thereby initializing the first electrode of the light-emitting element LED.

The ninth transistor T9 may be electrically connected to the second scan line SL2, the second electrode CE2 of the storage capacitor Cst, and the sustain voltage line VSL. The ninth transistor T9 is turned on according to a second scan signal GB transferred through the second scan line SL2 and may transfer the sustain voltage VSUS to the second node N2, for example, the second electrode CE2 of the storage capacitor Cst during the initialization section and the data-write section.

Each of the eighth transistor T8 and the ninth transistor T9 may be electrically connected to the second node N2, for example, the second electrode CE2 of the storage capacitor Cst. In an embodiment, during the initialization section and the data-write section, the eighth transistor T8 may be turned off and the ninth transistor T9 may be turned on. During an emission section, the eighth transistor T8 may be turned on and the ninth transistor T9 may be turned off. Because the sustain voltage VSUS is transferred to the second node N2 during the initialization section and the data-write section, uniformity (e.g., long range uniformity (LRU)) in brightness of the display apparatus depending on a voltage drop of the first voltage line VDDL may be improved.

The storage capacitor Cst includes the first electrode CE1 and the second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, the sustain voltage line VSL, and the first electrode of the light-emitting element LED. The auxiliary capacitor Ca may prevent a black brightness from rising when the sixth transistor T6 is turned off by storing and maintaining a voltage corresponding to a voltage difference between the first electrode of the light-emitting element LED and the sustain voltage line VSL while the seventh transistor T7 and the ninth transistor T9 are turned on.

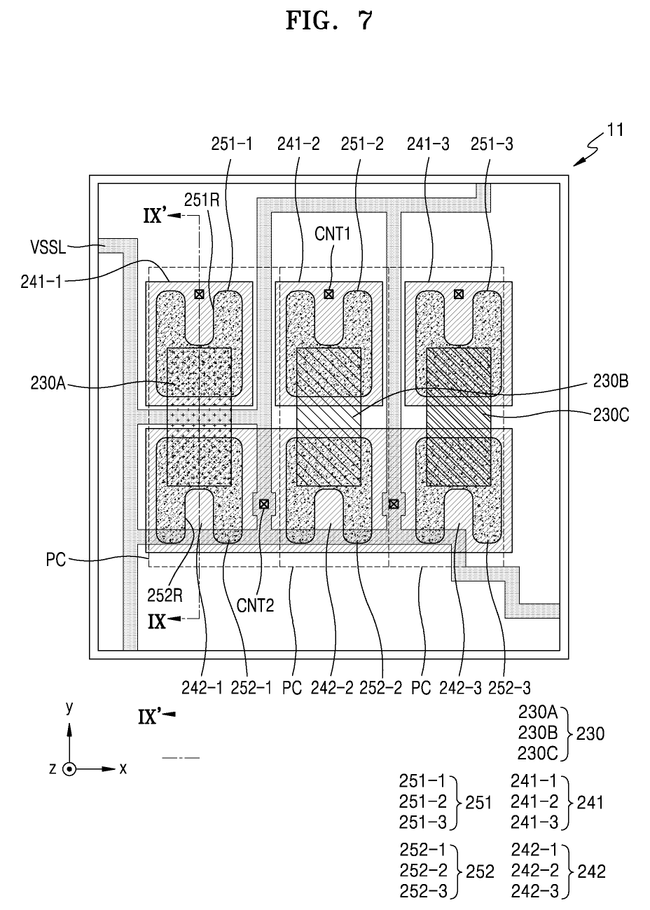

FIG. 7 is a schematic plan view of the first island portion 11 of the display apparatus according to an embodiment of the invention.

Referring to FIG. 7, light-emitting elements may be disposed in the first island portion 11. In an embodiment, as shown in FIG. 7, the light-emitting elements disposed in the first island portion 11 may include first to third light-emitting diodes 230A, 230B, and 230C that respectively emit light of different colors from each other. In an embodiment, for example, one of the first to third light-emitting diodes 230A, 230B, and 230C may emit red light, another may emit green light, and the remaining one may emit blue light.

In an embodiment, as shown in FIG. 7, three light-emitting diodes 230 may be disposed and three first electrode pads 241 may respectively correspond (overlap or be connected to) to the light-emitting diodes 230, but the invention is not limited thereto. In another embodiment, two or four or more light-emitting diodes 230 and two or four or more first electrode pads 241 may be disposed in the first island portion 11. Hereinafter, for convenience of description, embodiments where three light-emitting diodes 230 and three first electrode pads 241 are disposed in the first island portion 11 will be mainly described in detail.

In an embodiment, each of the light-emitting diodes 230 may be electrically connected to the pixel driving circuit portion PC through the first electrode pad 241 (or a first electrode layer), and be electrically connected to the second voltage line VSSL, which is a common power line, through a second electrode pad 242 (or a second electrode layer).

In a plan view (or when viewed in z direction), the first electrode pads 241 may be disposed apart from each other in one direction, for example, the first direction (e.g., the x direction or -x direction). In an embodiment, as shown in FIG. 7, the first electrode pads 241 may include a first first electrode pad 241-1, a second first electrode pad 241-2, and a third first electrode pad 241-3. The first first electrode pad 241-1, the second first electrode pad 241-2, and the third first electrode pad 241-3 may be disposed apart from each other in the first direction (e.g., the x direction or -x direction). The first first electrode pad 241-1 and the third first electrode pad 241-3 may be disposed on opposite sides with the second first electrode pad 241-2 therebetween. Each of the first first electrode pad 241-1, the second first electrode pad 241-2, and the third first electrode pad 241-3 may be electrically connected to the pixel driving circuit portion PC, for example, a transistor, through a first contact hole CNT1.

In a plan view, the second electrode pad 242 may be apart from the first electrode pads 241 in a direction, for example, the second direction (e.g., the y direction or -y direction) crossing an arrangement direction of the first electrode pads 241. The light-emitting elements may share (or be commonly connected to) one second electrode pad 242. In an embodiment, for example, a first portion 242-1 of the second electrode pad 242 may be electrically connected to a first light-emitting diode 230A, which is the first light-emitting element, a second portion 242-2 of the second electrode pad 242 may be electrically connected to a second light-emitting diode 230B, which is the second light-emitting element, and a third portion 242-3 of the second electrode pad 242 may be electrically connected to a third light-emitting diode 230C, which is the third light-emitting element, and the first to third portions 242-1, 242-2, and 242-3 may be integrally connected. The second portion 242-2 of the second electrode pad 242 may be located between the first portion 242-1 and the third portion 242-3. In an embodiment, the second electrode pad 242 may be an integral pad extending in the first direction and divided into the first portion 242-1, the second portion 242-2, and the third portion 242-3.

The first portion 242-1 of the second electrode pad 242 may be disposed adjacent to one of the first electrode pads 241, for example, the first first electrode pad 241-1 in the second direction (e.g., the y direction or -y direction). The second portion 242-2 of the second electrode pad 242 may be disposed adjacent to another of the first electrode pads 241, for example, the second first electrode pad 241-2 in the second direction (e.g., the y direction or -y direction). The third portion 242-3 of the second electrode pad 242 may be disposed adjacent to the remaining one of the first electrode pads 241, for example, the third first electrode pad 241-3 in the second direction (e.g., the y direction or -y direction).

The second electrode pad 242 may be electrically connected, through a second contact hole CNT2, to the second voltage line VSSL extending or passing through the first island portion 11. The second voltage line VSSL may include a plurality of branches. One of the branches may pass between the first portion 242-1 and the second portion 242-2, and another may pass between the second portion 242-2 and the third portion 242-3. Although FIG. 7 shows two contact holes CNT2 disposed between the first portion 242-1 and the second portion 242-2 and between the second portion 242-2 and the third portion 242-3, the invention is not limited thereto. In an embodiment, one second contact hole CNT2 may be disposed between the first portion 242-1 and the second portion 242-2, or between the second portion 242-2 and the third portion 242-3.

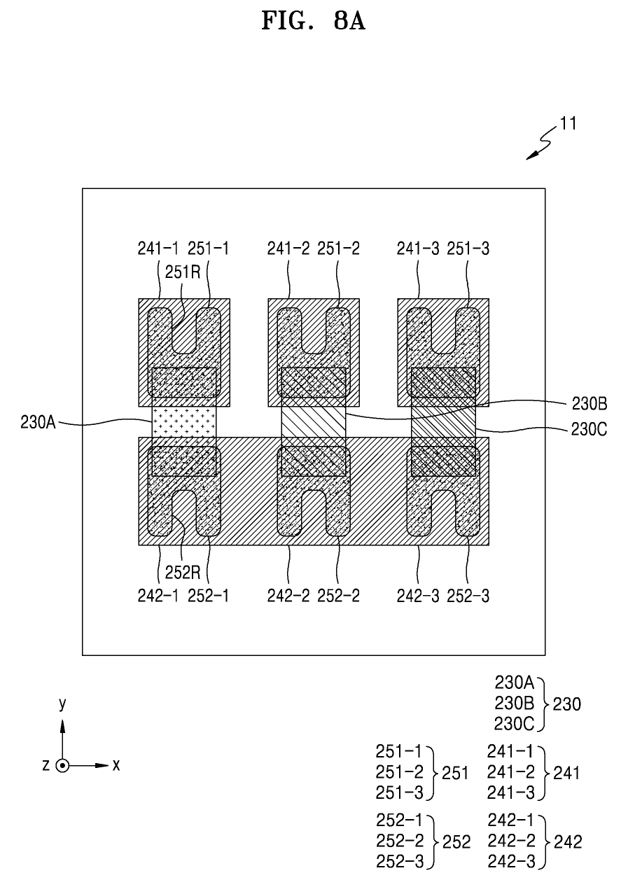

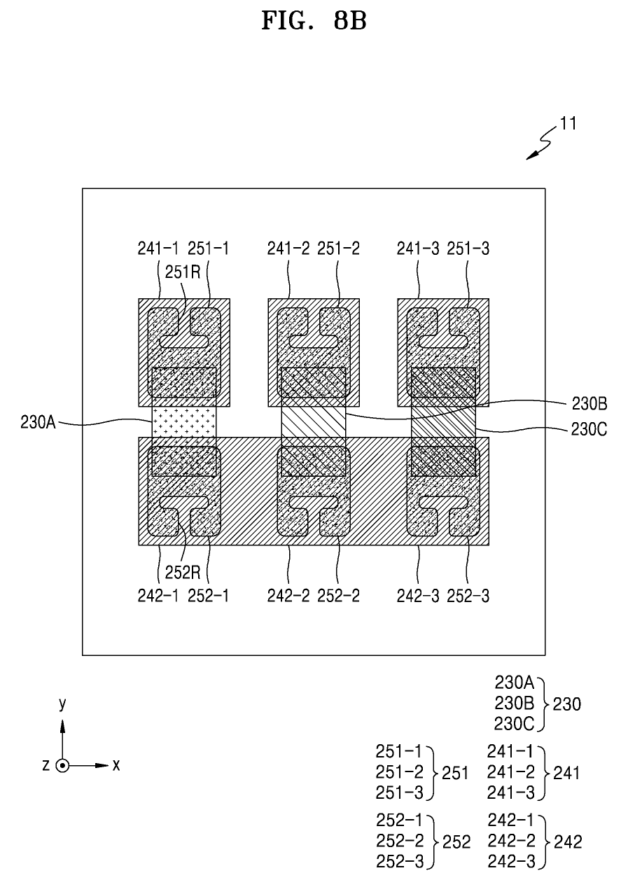

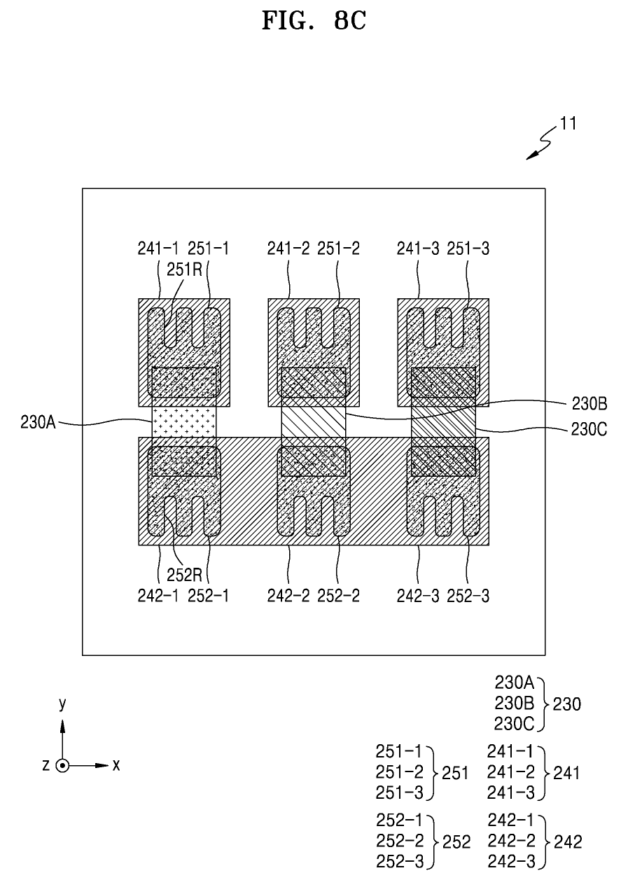

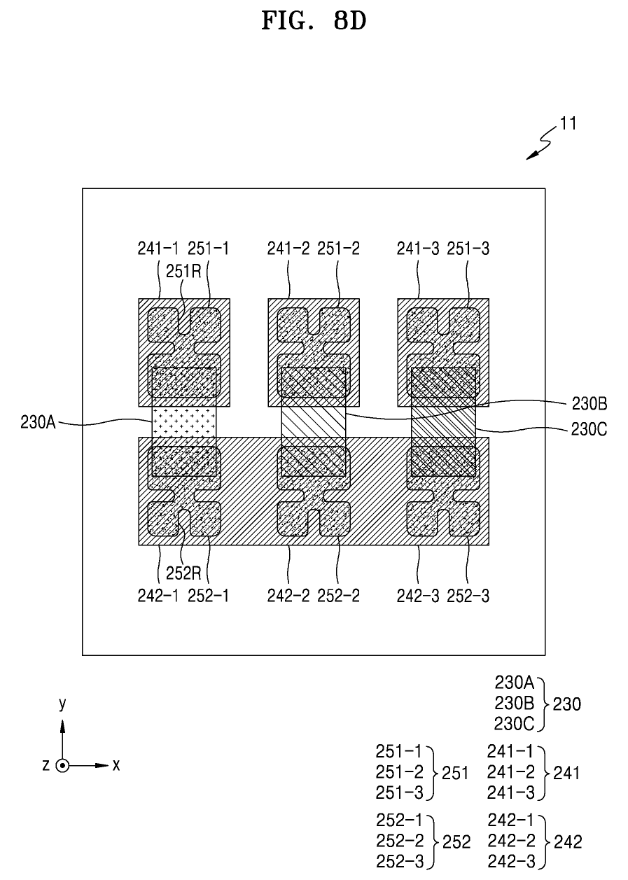

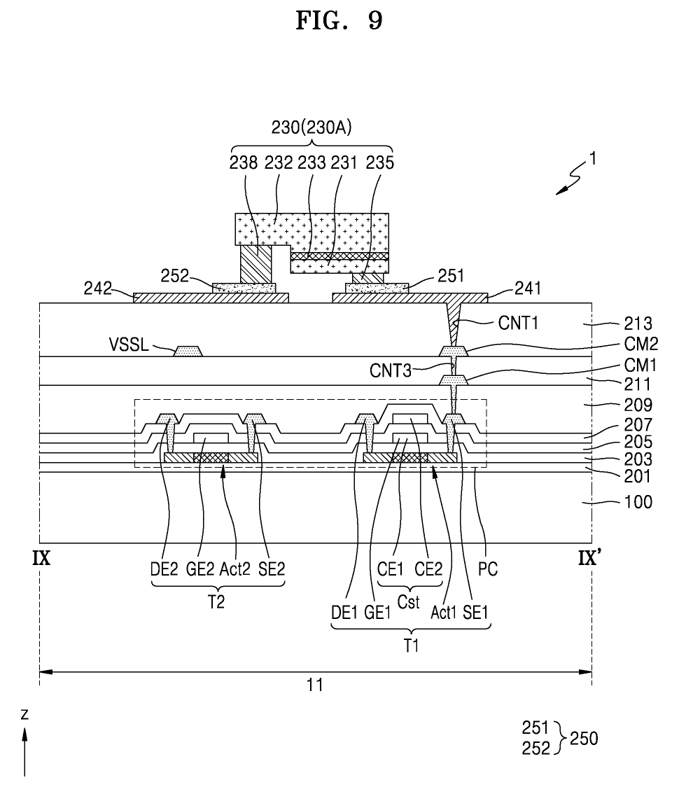

FIGS. 8A to 8D are excerpted plan views of the first and second electrode pads 241 and 242, the light-emitting diode 230, and a bump metal 250 disposed in the first island portion 11 of the display apparatus 1 according to embodiments of the invention. FIG. 9 is a cross-sectional view of the first island portion 11 of the display apparatus 1 according to an embodiment of the invention and corresponds to a cross-sectional view taken along line IX-IX' of FIG. 7.

Referring to FIGS. 7 to 9, in an embodiment, the pixel driving circuit portion PC and the light-emitting diode 230 as the light-emitting element electrically connected to the pixel driving circuit portion PC are disposed on the substrate 100. Although FIG. 9 shows that the light-emitting diode 230 is the first light-emitting diode 230A in an embodiment, the invention is not limited thereto. The structure of the second light-emitting diode 230B and the pixel driving circuit portion PC, and the structure of the third light-emitting diode 230C and the pixel driving circuit portion PC are the same as the structure shown in FIG. 9.

In an embodiment, as described above with reference to FIGS. 6A to 6C, the pixel driving circuit portion PC may include the transistors and the storage capacitor Cst. For convenience of illustration and description, FIG. 9 shows the first transistor T1 and the second transistor T2 among the transistors of the pixel driving circuit portion PC.

In an embodiment, a buffer layer 201 is disposed between the substrate 100 and the pixel driving circuit portion PC and may prevent impurities from penetrating the transistor. The buffer layer 201 may include an inorganic insulating material such as silicon oxide, silicon nitride, and silicon oxynitride, and be defined by a single layer or a multi-layer including at least one selected from the above inorganic insulating materials.

The first transistor T1 may include a first semiconductor layer Act1 and a first gate electrode GE1. A source region and a drain region of the first semiconductor layer Act1 may be respectively and electrically connected to a first source electrode SE1 and/or a first drain electrode DE1. The second transistor T2 may include a second semiconductor layer Act2 and a second gate electrode GE2. A source region and a drain region of the second semiconductor layer Act2 may be respectively and electrically connected to a second source electrode SE2 and/or a second drain electrode DE2.

Although FIG. 9 shows an embodiment including top gate- type transistors in which the first and second gate electrodes GE1 and GE2 are disposed over the first and second semiconductor layers Act1 and Act2 with a gate insulating layer 203 therebetween, but the first and second transistors T1 and T2 may be bottom gate-type transistors in another embodiment.

In an embodiment, the first and second semiconductor layers Act1 and Act2 may include polycrystalline silicon. In an embodiment, the first and second semiconductor layers Act1 and Act2 may include amorphous silicon, an oxide semiconductor, or an organic semiconductor. The first and second gate electrodes GE1 and GE2 may include a low-resistance metal material. The first and second gate electrode GE1 and GE2 may include a conductive material including at least one selected from molybdenum (Mo), aluminum (Al), copper (Cu), and titanium (Ti) and be defined by a single layer or a multi-layer including at least one selected from the above materials.

The gate insulating layer 203 may include an inorganic insulating material such as silicon oxide, silicon nitride, and silicon oxynitride, and be defined by a single layer or a multi-layer including at least one selected from the above materials.

The storage capacitor Cst may include the first electrode CE1 and the second electrode CE2 overlapping each other with a first interlayer insulating layer 205 therebetween. In an embodiment, the storage capacitor Cst may overlap the first transistor T1. In an embodiment, as shown in FIG. 9, the first gate electrode GE1 of the first transistor T1 may serve as the first electrode CE1 of the storage capacitor Cst. In another embodiment, the storage capacitor Cst may not overlap the first transistor T1. The storage capacitor Cst may be covered by a second interlayer insulating layer 207. The second electrode CE2 of the storage capacitor Cst may include a conductive material including at least one selected from molybdenum (Mo), aluminum (Al), copper (Cu), and titanium (Ti) and be defined by a multi-layer or a single layer including at least one selected from the above materials.

The first and second source electrodes SE1 and SE2 and the first and second drain electrodes DE1 and DE2 may be located on the same layer, for example, the second interlayer insulating layer 207, and may include the same material. The first and second source electrodes SE1 and SE2 and the first and second drain electrodes DE1 and DE2 may each include a conductive material including at least one selected from molybdenum (Mo), aluminum (Al), copper (Cu), and titanium (Ti) and be defined by a multi-layer or a single layer including at least one selected from the above materials.

The first interlayer insulating layer 205 and the second interlayer insulating layer 207 may include an inorganic insulating material such as silicon oxide, silicon nitride, and silicon oxynitride, and be defined by a single layer or a multi-layer including at least one selected from the above inorganic insulating materials. The first and second transistors T1 and T2 and the storage capacitor Cst may be covered by a first organic insulating layer 209.

A second organic insulating layer 211 and a third organic insulating layer 213 may be sequentially disposed on the first organic insulating layer 209. The first organic insulating layer 209, the second organic insulating layer 211, and the third organic insulating layer 213 may include an organic insulating material. The organic insulating material may include, for example, a general-purpose polymer such as polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof.

The second voltage line VSSL may be disposed on the second organic insulating layer 211. Although not shown, the first voltage line VDDL (FIGS. 6A to 6C) may be disposed on the first organic insulating layer 209 or the second organic insulating layer 211.

The first electrode pad 241 may be disposed on the third organic insulating layer 213. The first electrode pad 241 may be connected to a second contact metal CM2 through the first contact hole CNT1, and the second contact metal CM2 may be connected to a first contact metal CM1 through a third contact hole CNT3. Although FIG. 9 shows an embodiment where the first electrode pad 241 is electrically connected to the first transistor T1 through the first and second contact metals CM1 and CM2, the invention is not limited thereto. As described with reference to FIGS. 6B and 6C, the pixel driving circuit portion PC may further include the sixth transistor T6 (FIGS. 6B and 6C), and in this case, the first electrode pad 241 may be electrically connected to the sixth transistor T6 (FIGS. 6B and 6C) through the first and second contact holes CM1 and CM2. The sixth transistor T6 (FIGS. 6B and 6C) may have substantially the same structure as the first transistor T1.

The second electrode pad 242 may be disposed in (or directly on) a same layer as the first electrode pad 241, for example, on the third organic insulating layer 213. As described above with reference to FIG. 7, the second electrode pad 242 may be electrically connected to the second voltage line VSSL through the second contact hole CNT2 (FIG. 7).

The light-emitting diode 230 may be an inorganic light-emitting diode. In an embodiment, for example, the light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232.

The first semiconductor layer 231 may include, for example, a p-type semiconductor layer. The p-type semiconductor layer may be selected from among semiconductor materials having a composition formula of InxAlyGa1-x-yN (0≤x≤1, 0≤y≤1, 0≤x+y≤1), such as GaN, AlN, AlGaN, InGaN, InN, InAlGaN, AlInN, or the like, and may be doped with a p-type dopant such as Mg, Zn, Ca, Sr, or Ba.

The second semiconductor layer 232 may include, for example, an n-type semiconductor layer. The n-type semiconductor layer may be selected from among semiconductor materials having a composition formula of InxAlyGa1-x-yN (0≤x≤1, 0≤y≤1, 0≤x+y≤1), such as GaN, AlN, AlGaN, InGaN, InN, InAlGaN, AlInN, or the like, and may be doped with an n-type dopant such as Si, Ge, or Sn.

The intermediate layer 233 is a region in which electrons and holes recombine, and when electrons and holes recombine, they transition to a lower energy level and light having a corresponding wavelength may be generated. The intermediate layer 233 may include, for example, a semiconductor material having a composition formula of InₓAl_{y}Ga_{1-x-y}N (0≤x≤1, 0≤y≤1, 0≤x+y≤1), and be formed in a single quantum-well structure or a multi quantum-well structure (MQW). In addition, the intermediate layer 233 may include a quantum-wire structure or a quantum-dot structure.

In an embodiment, as described with reference to FIG. 9, the first semiconductor layer 231 includes a p-type semiconductor layer, and the second semiconductor layer 232 includes an n-type semiconductor layer, but the invention is not limited thereto. In another embodiment, the first semiconductor layer 231 may include an n-type semiconductor layer, and the second semiconductor layer 232 may include a p-type semiconductor layer.

The first electrode 235 and the second electrode 238 of the light-emitting diode 230 may be electrically connected to the first electrode pad 241 and the second electrode pad 242 through the bump metal 250.

The first electrode pad 241 and the second electrode pad 242 may be electrically connected to the light-emitting diode 230 by disposing the bump metal 250 on each of the first electrode pad 241 and the second electrode pad 242, and then applying preset heat thereto, and disposing the light-emitting diode 230 with preset pressure (or by pressing the light-emitting diode 230 to the bump metal 250. In an embodiment, for example, the light-emitting diode 230 may be electrically connected to the first electrode pad 241 through a first bump metal 251 between the light-emitting diode 230 and the first bump metal 251. The light-emitting diode 230 may be electrically connected to the second electrode pad 242 through a second bump metal 252 between the light-emitting diode 230 and the second bump metal 252.

Referring to FIGS. 7 to 9, the bump metals 250 may be respectively disposed on relevant electrode pads. In an embodiment, the bump metal 250 may include metal such as gold (Au), nickel (Ni), and indium (In).

The first bump metals 251 may be respectively disposed on the relevant first first electrode pad 241-1, the second first electrode pad 241-2, and the third first electrode pad 241-3. In an embodiment, for example, a first first bump metal 251-1 may be disposed on the first first electrode pad 241-1, a second first bump metal 251-2 may be disposed on the second first electrode pad 241-2, and a third first bump metal 251-3 may be disposed on the third first electrode pad 241-3. In such an embodiment, the first bump metal 251 may be disposed to overlap the first electrode pad 241 in a plan view (or in the z direction). In an embodiment, for example, the first first bump metal 251-1 may overlap the first first electrode pad 241-1, the second first bump metal 251-2 may overlap the second first electrode pad 241-2, and the third first bump metal 251-3 may overlap the third first electrode pad 241-3. In a plan view, the first first bump metal 251-1, the second first bump metal 251-2, and the third first bump metal 251-3 may be sequentially disposed apart from each other in the first direction (e.g., the x direction).

The second bump metal 252 may be disposed on the second electrode pad 242, for example, the first to third portions 242-1, 242-2, and 242-3. In an embodiment, for example, a first second bump metal 252-1 may be disposed on the first portion 242-1, a second second bump metal 252-2 may be disposed on the second portion 242-2, and a third second bump metal 252-3 may be disposed on the third portion 242-3. In such an embodiment, the second bump metal 252 may be disposed to overlap the second electrode pad 242 in a plan view. In an embodiment, for example, the first second bump metal 252-1 may overlap the first portion 242-1, the second second bump metal 252-2 may overlap the second portion 242-2, and the third second bump metal 252-3 may overlap the third portion 242-3. The first second bump metal 252-1, the second second bump metal 252-2, and the third second bump metal 252-3 may be sequentially disposed apart from each other in the first direction (e.g., the x direction). In this case, it will be understood that the first first bump metal 251-1 and the first second bump metal 252-1 may be disposed to face each other in the second direction (e.g., the y direction), the second first bump metal 251-2 and the second second bump metal 252-2 may be disposed to face each other in the second direction (e.g., the y direction), and the third first bump metal 251-3 and the third second bump metal 252-3 may be disposed to face each other in the second direction (e.g., the y direction).

Hereinafter, for convenience of description, the first first bump metal 251-1 and the first second bump metal 252-1 are mainly described. It will be understood that description of the first first bump metal 251-1 and the first second bump metal 252-1 is applicable to another first bump metal 251 and another second bump metal 252.

In an embodiment, in a plan view, the first bump metal 251 may have a smaller size (e.g., planar area) than the first electrode pad 241. In an embodiment, as an example, in a plan view, the first first bump metal 251-1 may be disposed within the circumference of the first first electrode pad 241-1. In addition, in an embodiment, in a plan view, the second bump metal 252 may have a smaller size than the second electrode pad 242. In an embodiment, for example, in a plan view, the first second bump metal 252-1 may be disposed within the circumference of the second electrode pad 242, for example, the first portion 242-1.

In an embodiment, the first bump metal 251 may include a first depression portion 251R. The first depression portion 251R may be a portion concavely recessed inward from one edge of the first bump metal 251 in a plan view. The first depression portion 251R may expose the first electrode pad 241 under the first bump metal 251. The first first bump metal 251-1 may include a first edge 251S1 adjacent to the first second bump metal 252-1, and a second edge 251S2 opposite to the first edge 251S1. The first depression portion 251R, for example, may be concavely recessed inward from the second edge 251S2. In an embodiment, as shown in FIG. 8A, the first depression portion 251R may have a shape recessed in a straight line form in the second direction (e.g., the y direction) from the second edge 251S2. Alternatively, in another embodiment, as shown in FIG. 8B, the first depression portion 251R may have a shape recessed in an inverted 'T' form from the second edge 251S2. Hereinafter, for convenience of description, embodiments where the first depression portion 251R has a shape recessed in a straight line form will be mainly described.

In an embodiment, the second bump metal 252 may include a second depression portion 252R. The second depression portion 252R may be a portion concavely recessed inward from one edge of the second bump metal 252. The second depression portion 252R may expose the second electrode pad 242 under the second bump metal 252. The first second bump metal 252-1 may include a first edge 252S1 adjacent to the first first bump metal 251-1, and a second edge 252S2 opposite to the first edge 252S1. In such an embodiment, the first edge 252S1 of the first second bump metal 252-1 may face the first edge 251S1 of the first first bump metal 251-1. The second depression portion 252R, for example, may be concavely recessed inward from the second edge 252S2. In an embodiment, as shown in FIG. 8A, the second depression portion 252R may have a shape recessed in a straight line form in the second direction (e.g., the y direction) from the second edge 252S2. Alternatively, in another embodiment, as shown in FIG. 8B, the second depression portion 252R may have a shape recessed in an inverted 'T' form from the second edge 252S2. Hereinafter, for convenience of description, embodiments where the second depression portion 252R has a shape recessed in a straight line form will be mainly described.

In an embodiment, as described above, because the first bump metal 251 includes the first depression portion 251R, and the second bump metal 252 includes the second depression portion 252R, a phenomenon of the bump metals 250 being pushed may be effectively prevented. In a process of electrically connecting the light-emitting element and the first electrode pad 241 and the second electrode pad 242 to each other using the bump metals 250, a phenomenon of the bump metals 250 being pushed may occur. In an embodiment, for example, in the process of disposing the bump metals 250 on the first electrode pad 241 and the second electrode pad 242, and then applying heat and pressure to dispose the light-emitting diode 230, the bump metals 250 on the first electrode pad 241 and the second electrode pad 242 may deviate from the boundaries of the electrode pads 241 and 242 and be detached to the surroundings of the electrode pads 241 and 242, and/or uniformity in thickness of the bump metal 250 may deteriorate. In embodiments of the invention, because the first bump metal 251 includes the first depression portion 251R, the metal material may spread to the first depression portion 251R when heat and pressure are applied. In such embodiments, in the second bump metal 252, the metal material may spread to the second depression portion 252R when heat and pressure are applied. Accordingly, the bump metal 250 may be effectively prevented from spreading to deviate from the boundaries of the electrode pads 241 and 242, and in addition, an issue such as reduction in uniformity, such as the thickness of the bump metal 250 being excessively thick in a specific portion, may be effectively prevented. In addition, through the first depression portion 251R and the second depression portion 252R, the first bump metal 251 and the second bump metal 252 may secure an area in contact with the electrode pads 241 and 242 while providing a space into which the metal material may flow. Accordingly, the bump metals 250 may not be detached from the electrode pads 241 and 242.

In an embodiment, as described above, the first light-emitting element 230A may include the first electrode 235 in contact with a portion of the first first bump metal 251-1 and the second electrode 238 in contact with a portion of the first second bump metal 252-1. In such an embodiment, the first depression portion 251R may be located not to overlap the first electrode 235 in a plan view. In addition, in an embodiment, the second depression portion 252R may be located not to overlap the second electrode 238 in a plan view. Accordingly, the bump metals 250 may be sufficiently in contact with the first electrode 235 and/or the second electrode 238.

Referring to FIG. 8C, in an embodiment, the first depression portion 251R may be provided in plurality for each bump metal. The plurality of first depression portions 251R may be disposed apart from each other along one edge, for example, the second edge 251S2 of the first first bump metal 251-1. In such an embodiment, the plurality of first depression portions 251R may be located not to overlap the first electrode 235 in a plan view. In addition, in an embodiment, the second depression portion 252R may be provided in plurality. The plurality of second depression portions 252R may be disposed apart from each other along one edge, for example, the second edge 252S2 of the first second bump metal 252-1, and in a plan view, be located not to overlap the second electrode 238.

Referring to FIG. 8D, in an embodiment, the first first bump metal 251-1 may have a polygonal shape. In such an embodiment, the first edge S1 of the first first bump metal 251-1 may be an edge overlapping the first electrode 235 in a plan view. The first depression portion 251R may be provided in plurality for each bump metal. The plurality of first depression portions 251R may be respectively disposed to be recessed from the remaining edges other than the first edge S1 from the first first bump metal 251-1. In an embodiment, for example, the first-bump metal 251-1 may have a quadrangular shape. Three first depression portions 251R may be respectively disposed in the remaining three edges other than the first edge S1. However, in another embodiment, it will be understood that the first first bump metal 251-1 may be provided in a shape of a pentagon or a hexagon, and four or five first depression portions 251R may be respectively disposed in the remaining four or five edges other than the first edge S1. In addition, in an embodiment where the first first bump metal 251-1 has a circular shape, the plurality of first depression portions 251R may be disposed apart from each other along the circumference of the first first bump metal 251-1 and be disposed not to overlap the first electrode 235 in a plan view.

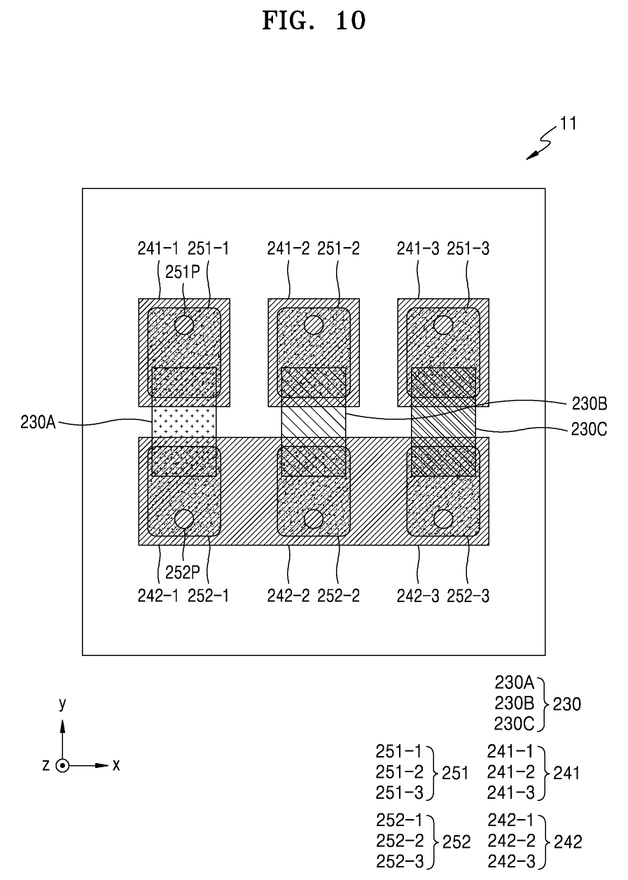

FIG. 10 is an excerpted plan view of the first and second electrode pads 241 and 242, the light-emitting diode 230, and the bump metal 250 disposed in the first island portion 11 of the display apparatus 1 according to embodiments of the invention. The display apparatus 1 shown in FIG. 10 is substantially the same as the display apparatus described above except for metal bumps, only differences will be mainly described in detail.

Referring to FIG. 10, in an embodiment, the first bump metal 251 may be provided a first opening 251P defined therein. The first opening 251P may be an opening defined or formed through the first bump metal 251. The first opening 251P may expose the first electrode pad 241 under the first bump metal 251. In an embodiment, the first opening 251P may have a circular shape. However, the invention is not limited thereto, and the first opening 251P may have various shapes such as a polygon.

In an embodiment, the first opening 251P may be disposed adjacent or close to one edge of the first bump metal 251. In an embodiment, for example, the first opening 251P may be disposed adjacent to the second edge 251S2 of the first first bump metal 251-1. In addition, the first opening 251P may be located not to overlap the first electrode 235 in a plan view (or in the z direction).

In an embodiment, the second bump metal 252 may be provided with a second opening 252P. The second opening 252P may be an opening defined or formed through the second bump metal 252. The second opening 252P may expose the second electrode pad 242 under the second bump metal 252. In an embodiment, the second opening 252P may have a circular shape. However, the invention is not limited thereto, and the second opening 252P may have various shapes such as a polygon.

In an embodiment, the second opening 252P may be disposed adjacent or close to one edge of the second bump metal 252. In an embodiment, for example, the second opening 252P may be disposed adjacent to the second edge 252S2 of the first second bump metal 252-1. In addition, the second opening 252P may be located not to overlap the second electrode 238 in a plan view.

In an embodiment, as shown in FIG. 10, a single first opening 251P or a single second opening 252P is provided for each metal bump, but the invention is not limited thereto. In another embodiment, the first opening 251P and the second opening 252P may be provided in plurality. In an embodiment, for example, the plurality of first openings 251P may be disposed apart from each other along one edge, for example, the second edge 251S2 of the first first bump metal 251-1. The plurality of first openings 252P may be disposed apart from each other along one edge, for example, the second edge 252S2 of the first first bump metal 252-1.

Alternatively, in another embodiment, the plurality of first openings 251P may be respectively disposed adjacent to the remaining edges other than the first edge 251S1 of the first first bump metal 251-1 overlapping the first electrode 235. The plurality of second openings 252P may be respectively disposed adjacent to the remaining edges other than the first edge 252S1 of the first second bump metal 252-1 overlapping the second electrode 238.

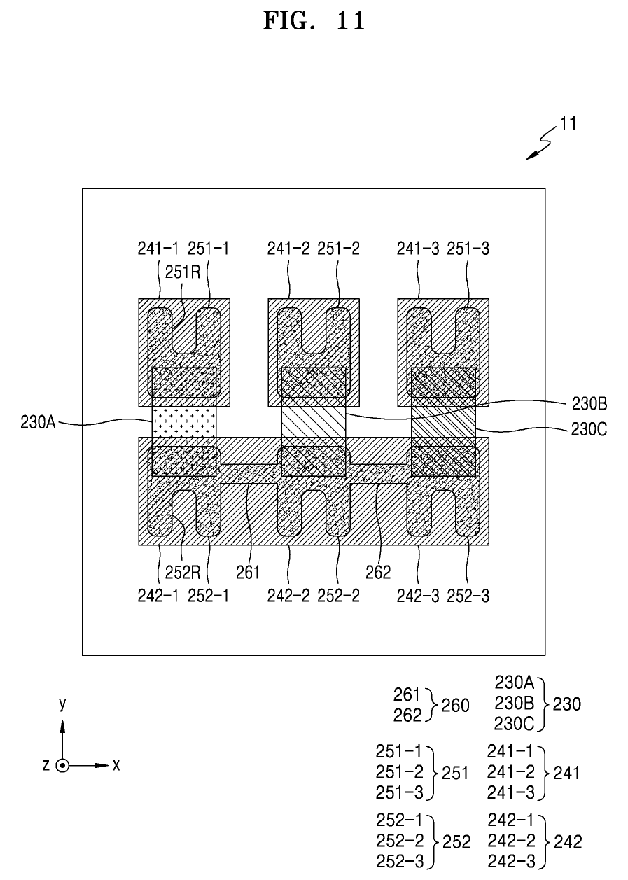

FIG. 11 is an excerpted plan view of the first and second electrode pads 241 and 242, the light-emitting diode 230, and the bump metal 250 disposed in the first island portion 11 of the display apparatus 1 according to embodiments of the invention. The display apparatus 1 shown in FIG. 11 is substantially the same as the display apparatus described above except for a connection metal 260, only differences will be mainly described in detail.

Referring to FIG. 11, in an embodiment, the first second bump metal 252-1, the second second bump metal 252-2, and the third second bump metal 252-3 may be disposed on the second electrode pad 242 and be apart from each other in the first direction (e.g., the x direction). In such an embodiment, the second bump metals 252 may be connected to each other by a connection metal 260.

The connection metal 260 may be disposed in (or directly on) a same layer as the second bump metal 252. In an embodiment, for example, the connection metal 260 may be disposed on the second electrode pad 242. In an embodiment, the connection metal 260 may include a first connection metal 261 and a second connection metal 262. The first connection metal 261 extends in the first direction (e.g., the x direction) and may connect the first second bump metal 252-1 and the second second bump metal 252-2 to each other. The second connection metal 262 extends in the first direction (e.g., the x direction) and may connect the second second bump metal 252-2 and the third second bump metal 252-3 to each other.

In an embodiment, a width W1 of the connection metal 260 may be less than a width W2 of the second bump metal 252. In such an embodiment, the width of the metal may mean a length in the second direction (e.g., the y direction). The width W1 of the first connection metal 261 may be less than the width W2 of the first second bump metal 252-1, and the width W1 of the second connection metal 262 may be less than the width W2 of the second second bump metal 252-2.

Because the connection metal 260 is formed to be less than the width of the second bump metal 252, a space into which the metal material may flow may be provided compared to a case where the second bump metal 252 is integrally formed to cover the first light-emitting element, the second light-emitting element, and the third light-emitting element. In addition, because an area in contact with the second electrode pad 242 may be increased compared to a case where the second bump metal 252 is disposed to be separated into the first second bump metal 252-1, the second second bump metal 252-2, and the third second bump metal 252-3, the second bump metal 252 may be prevented from being detached from the second electrode pad 242.

Although FIG. 11 shows an embodiment where a single first connection metal 261 or a single second connection metal 262 are disposed between two adjacent second bump metals, the invention is not limited thereto. In an embodiment, for example, the first connection metal 261 may be provided in plurality to connect the first second bump metal 252-1 and the second second bump metal 252-2 to each other. In such an embodiment, the plurality of first connection metals 261 may be disposed apart from each other in the second direction (e.g., the y direction). In addition, the second connection metal 262 may be provided in plurality to connect the second second bump metal 252-2 and the third second bump metal 252-3 to each other. In such an embodiment, the plurality of second connection metals 262 may be disposed apart from each other in the second direction (e.g., the y direction).

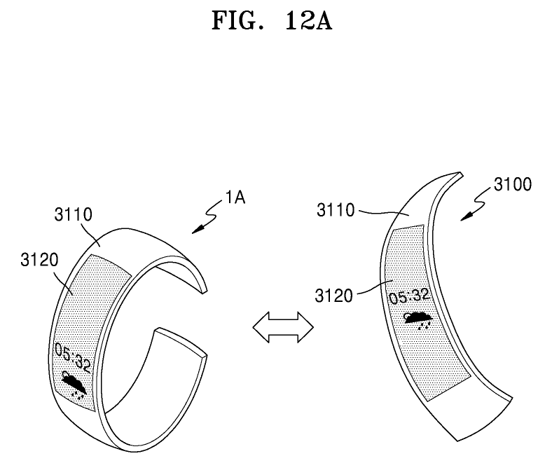

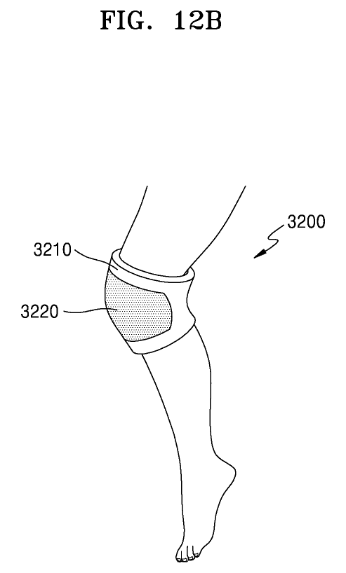

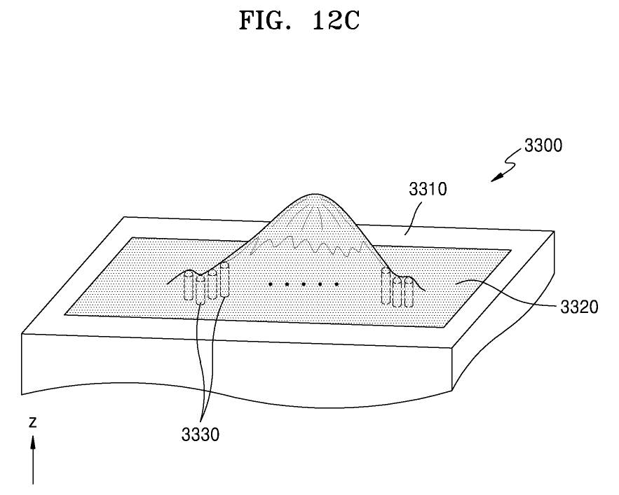

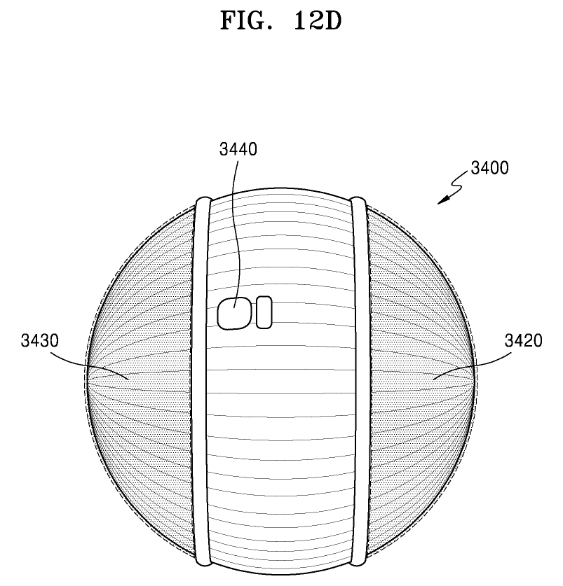

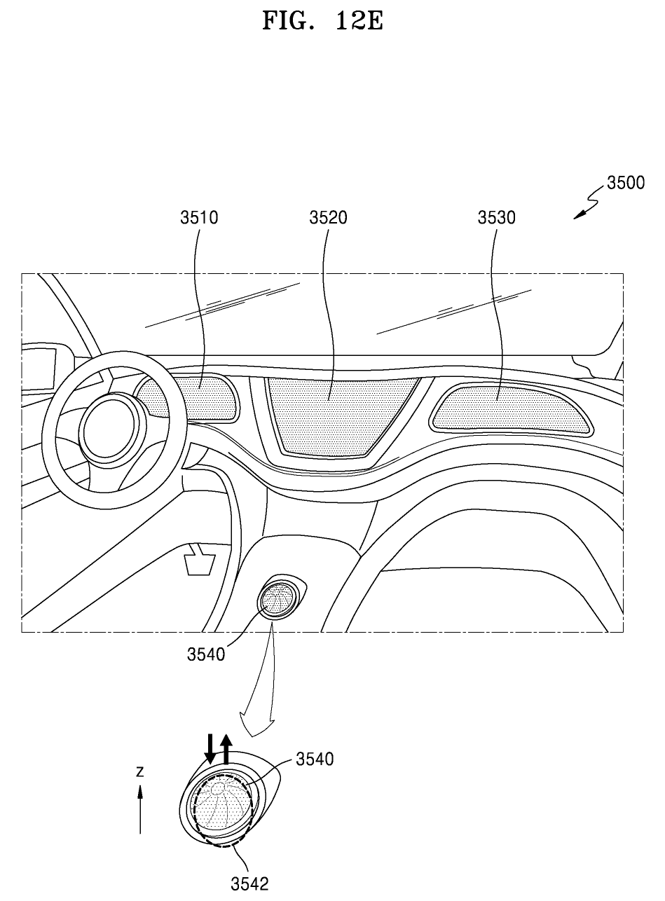

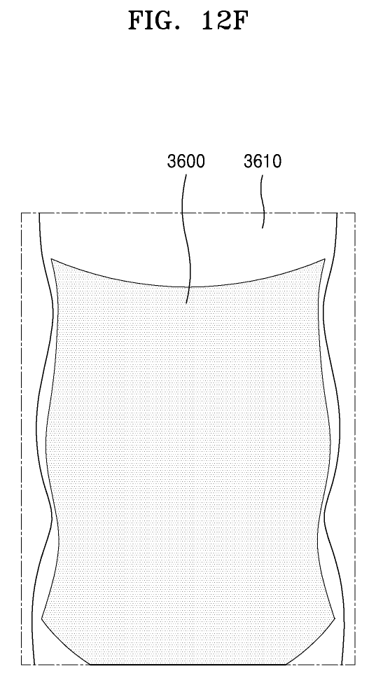

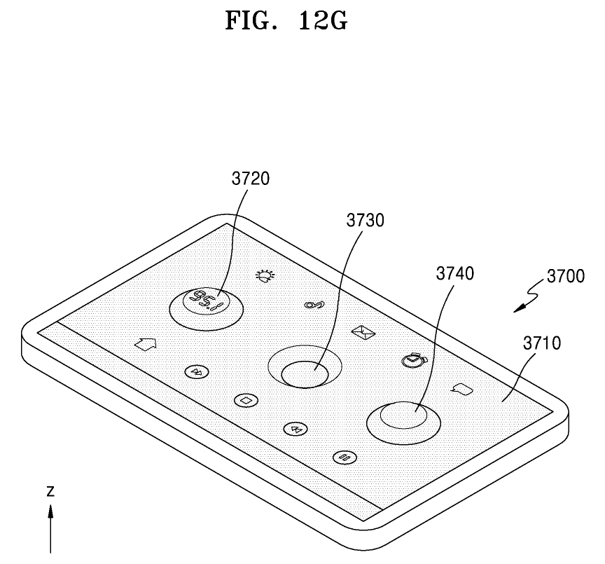

FIGS. 12A to 12G are respectively schematic perspective views of an electronic device including a display apparatus according to an embodiment of the invention.

Referring to FIG. 12A, the display apparatus according to an embodiment of the invention may be utilized in a wearable electronic device 3100 that may be worn on a portion of a user's body. The wearable electronic device 3100 may include a body portion 3110 and a display portion 3120 provided to the body portion 3110. The display apparatus according to embodiments of the invention may be used as the display portion 3120 of the wearable electronic device 3100. As shown in FIG. 13A, the wearable electronic device 3100 may be deformed. In an embodiment, the wearable electronic device 3100 may be used as a smartwatch or a smartphone according to a user’s selection.

FIG. 12B shows an embodiment where the electronic device is a medical electronic device 3200. In an embodiment, the medical electronic device 3200 may include a body portion 3210 and a light-emitting portion 3220. A display apparatus according to embodiments of the invention may be used as the light-emitting portion 3220 of the medical electronic device 3200. The light-emitting portion 3220 may emit light (e.g., infrared rays, visible rays, and the like) in a preset wavelength band to a patient’s body. In an embodiment, the body portion 3210 may include a stretchable fiber material and have a structure that may be worn on the body of a user of the light-emitting portion.

FIG. 12C shows an embodiment where the electronic device is an educational electronic device 3300. In an embodiment, the educational electronic device may include a display portion 3320 provided inside a frame 3310. The display portion 3320 may be used as the display apparatus according to the embodiments of the invention. An image such as the sea with crashing waves, a snow-covered mountain, or a volcano with flowing lava can be provided through the display portion 3320, and in this case, the display portion 3320 may be stretched in a height direction (e.g., a z direction) to reflect the height of the wave, mountain, or volcano. In an embodiment, a portion of the display portion 3320 may be configured to sequentially change its height in a direction in which the lava flows, thereby showing the movement of the lava three dimensionally. The educational electronic device 3300 may include a plurality of strokes 3330 disposed under, for example, on the rear surface of the display portion 3320 such that the display portion 3320 is stretched in the height direction. The strokes 3330 may be implemented to move in the third direction (e.g., the z direction or -z direction) such that an image expressed on the display portion 3320 has a height three dimensionally. In an embodiment, haptic information may be provided through the strokes 3330. Although FIG. 13C shows an embodiment where the electronic device is the educational electronic device 3300, the purpose thereof is not limited thereto as far as the educational electronic device 3300 provides preset image information.

In an embodiment, as described with reference to FIGS. 12A to 12C, an electronic device may have a variable shape, but the invention is not limited thereto. As in embodiments described below, the display apparatus according to embodiments of the invention may be used in an electronic device in which a portion (e.g., a screen) that may display images is fixed.

FIG. 12D shows an embodiment where the electronic device is a robot 3400. The robot 3400 may recognize a movement or object using a camera portion 3440 and express preset images to a user through display portions 3420 and 3430. In an embodiment, because the display apparatuses according to an embodiment of the invention may be stretched in various directions as described above, the display apparatuses may be assembled to a body frame having a hemispherical shape, and thus, the robot 3400 may include the display portions 3420 and 3430 that has a hemispherical shape.

FIG. 12E shows an embodiment where the electronic device is a vehicle display apparatus 3500. The vehicle display apparatus 3500 may include a cluster 3510, a center information display (CID) 3520, and/or a passenger display. Because the display apparatus according to an embodiment of the invention may be stretched in various directions, the display apparatus may be used in the cluster 3510, the CID 3520, and/or the passenger display without being restricted by the shape of an internal frame of the vehicle.

Although FIG. 12E shows an embodiment where the cluster 3510, the CID 3520, and/or the passenger display are separated from each other, the invention is not limited thereto. In another embodiment, two or more selected from the cluster 3510, the CID 3520, and the passenger display may be integrally connected.

In another embodiment, the vehicle display apparatus 3500 may include a button 3540 that may express preset images. Referring to an enlarged view of FIG. 12E, the button 3540 that has a hemispherical shape may include an object 3542 and a display apparatus disposed on the object 3542, where the object 3542 provides the feel of a button while moving in the z direction or -z-direction. In an embodiment, in the case where the object 3542 has a three-dimensionally round surface, the display apparatus may also have a three-dimensionally round surface.

FIG. 12F shows an embodiment where the electronic device is an electronic device 3600 for advertising or display. In an embodiment, the electronic device 3600 for advertising or display may be installed on a fixed structure 3610 such as a wall or pole. In a case where the structure 3610 includes an uneven surface as shown in FIG. 12F, the electronic device 3600 for advertising or display may be also disposed along the uneven surface of the structure 3610. In an embodiment, the electronic device 3600 for advertising or display may be installed on the structure 3610 using a heat shrink film.

FIG. 12G shows an embodiment where the electronic device is a controller 3700. The controller 3700 may include an image-type button. In an embodiment, for example, the controller 3700 may include first to third button regions 3720, 3730, and 3740 in which a portion of the display portion 3710 protrudes in the z direction or protrudes in the -z direction (or is recessed in the z direction). In an embodiment, the first and third button regions 3720 and 3740 may protrude in the z direction, and the second button region 3730 may protrude in the -z direction (or be recessed in the z direction).

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display apparatus comprising:
a substrate;
a transistor disposed on the substrate;
a first first electrode pad electrically connected to the transistor;
a first first bump metal connected to the first first electrode pad; and
a first light-emitting element electrically connected to the first first electrode pad through the first first bump metal,
wherein, in a plan view, the first first bump metal includes a first depression portion concavely recessed inward from one edge thereof.

2. The display apparatus of claim 1, wherein
the first light-emitting element includes a first electrode in contact with a portion of the first first bump metal, and
in the plan view, the first depression portion does not overlap the first electrode.

3. The display apparatus of claim 2, wherein
the first first bump metal is in a shape of a polygon in the plan view,
a first edge of the polygon overlaps the first electrode in the plan view,
the first depression portion is provided in plurality, and
a plurality of first depression portions are respectively recessed from remaining edges other than the first edge.

4. The display apparatus of claim 1, wherein the first depression portion has a shape recessed in a straight line shape from the one edge of the first first bump metal in the plan view.

5. The display apparatus of claim 1, wherein the first depression portion has a shape recessed in an inverted 'T' shape from the one edge of the first first bump metal in the plan view.

6. The display apparatus of claim 1, wherein
the first depression portion is provided in plurality, and
a plurality of first depression portions is disposed apart from each other along the one edge of the first first bump metal.

7. The display apparatus of claim 1, wherein, in the plan view, the first first bump metal has a smaller size than the first first electrode pad.

8. The display apparatus of claim 1, further comprising:
a second first electrode pad apart in a first direction from the first first electrode pad;
a second electrode pad apart from the first first electrode pad and the second first electrode pad in a second direction crossing the first direction; and
a first second bump metal connected to the second electrode pad to electrically connect the second electrode pad and the first light-emitting element to each other,
wherein, in the plan view, the first second bump metal includes a second depression portion concavely recessed inward from one edge thereof.

9. The display apparatus of claim 8, wherein the first depression portion is recessed from a second edge of the first first bump metal opposite to a first edge of the first first bump metal, which is adjacent to the first second bump metal.

10. The display apparatus of claim 8, wherein
the first light-emitting element includes a second electrode in contact with a portion of the first second bump metal, and
in the plan view, the second depression portion does not overlap the second electrode.

11. The display apparatus of claim 8, wherein the second depression portion is recessed from a second edge of the first second bump metal opposite to a first edge of the first second bump metal, which is adjacent to the first first bump metal.

12. The display apparatus of claim 8, further comprising:
a second second bump metal connected to the second electrode pad to electrically connect the second electrode pad and a second light-emitting element to each other; and
a connection metal disposed on the second electrode pad to connect the first second bump metal and the second second bump metal to each other.

13. The display apparatus of claim 12, wherein, in the plan view, a width of the connection metal is less than widths of the first second bump metal and the second second bump metal.

14. The display apparatus of claim 8, wherein, in the plan view, the first second bump metal has a smaller size than the second electrode pad.

15. A display apparatus comprising:
a substrate;
a transistor disposed on the substrate;
a first first electrode pad electrically connected to the transistor;
a first first bump metal connected to the first first electrode pad; and
a first light-emitting element electrically connected to the first first electrode pad through the first first bump metal,
wherein, in a plan view, the first first bump metal is provided with a first opening exposing the first first electrode pad.

16. The display apparatus of claim 15, wherein
the first light-emitting element includes a first electrode in contact with a portion of the first first bump metal, and
in the plan view, the first opening is defined not to overlap the first electrode.

17. The display apparatus of claim 15, further comprising:
a second first electrode pad apart in a first direction from the first first electrode pad;
a second electrode pad apart from the first first electrode pad and the second first electrode pad in a second direction crossing the first direction; and
a first second bump metal connected to the second electrode pad to electrically connect the second electrode pad and the first light-emitting element to each other,
wherein, in the plan view, the first second bump metal is provided with a second opening exposing the second electrode pad.

18. The display apparatus of claim 17, wherein
the first light-emitting element includes a second electrode in contact with a portion of the first second bump metal, and
in the plan view, the second opening is defined not to overlap the second electrode.

19. The display apparatus of claim 17, further comprising:
a second second bump metal connected to the second electrode pad to electrically connect the second electrode pad and a second light-emitting element to each other; and
a connection metal disposed on the second electrode pad to connect the first second bump metal and the second second bump metal to each other.

20. An electronic device including a display unit, wherein the electronic device comprises:
a display apparatus corresponding to the display unit; and
a frame which accommodates the display apparatus,
wherein the display apparatus comprises:
a substrate;
a transistor disposed on the substrate;
a first first electrode pad electrically connected to the transistor;
a first first bump metal connected to the first first electrode pad; and
a first light-emitting element electrically connected to the first first electrode pad through the first first bump metal,
wherein, in a plan view, the first first bump metal includes a first depression portion concavely recessed inward from one edge thereof.
